(19) United States
(12) Patent Application Publication
(10) Pub. No.: US 2025/0228075 A1
(43) Pub. Date: Jul. 10, 2025

(54) DISPLAY DEVICE AND METHOD OF MANUFACTURING THE SAME

(71) Applicant: Samsung Display Co., Ltd., Yongin-si (KR)

(72) Inventors: HOON KIM, Yongin-si (KR); WAN NAMGUNG, Yongin-si (KR); ROHYEON PARK, Yongin-si (KR); HEEJIN JEON, Yongin-si (KR)

(73) Assignee: Samsung Display Co., Ltd., Yongin-si (KR)

(21) Appl. No.: 18/946,084

(22) Filed: Nov. 13, 2024

(30) Foreign Application Priority Data
Jan. 5, 2024 (KR) 10-2024-0002039

(51) Int. Cl. H10K 59/122; H10K 50/19; H10K 59/12

(52) U.S. Cl. CPC H10K 59/122; H10K 50/19; H10K 59/1201

(57) ABSTRACT

A display device includes a base layer, a pixel defining layer including a pixel opening corresponding to a pixel area, a light emitting unit overlapping the pixel area, and including a charge generating layer, and a separation pattern overlapping a valley area, wherein the separation pattern includes a first pattern part protruding from an upper surface of the pixel defining layer to a first height, a second pattern part protruding from the upper surface of the pixel defining layer to a second height that is substantially same as the first height, and a third pattern part disposed between the first pattern part and the second pattern part and recessed from the first pattern part and the second pattern part toward the upper surface of the pixel defining layer, the charge generating layer is disconnected on the third pattern part.

### CROSS-REFERENCE TO RELATED APPLICATION(S)

This application claims priority to and benefits of Korean Patent Application No. 10-2024-0002039 under 35 U.S.C. § 119, filed on Jan. 5, 2024, in the Korean Intellectual Property Office, the entire contents of which are incorporated herein by reference.

### BACKGROUND

Embodiments described herein relate to a display device and a method of manufacturing the display device, and more particularly, to a display device including a charge generating layer.

Electronic devices such as smart phones, tablet personal computers (PCs), digital cameras, laptop computers, navigation devices, and televisions that provide images to users include display panels for displaying images.

For color display, the display panel is formed by dividing pixels into red pixels, green pixels, and blue pixels and may be divided into each pixel to form a light emitting layer having a color of the corresponding pixel. In general, a deposition method using a shadow mask is used for the light emitting layer, but defects such as mask sagging may occur, and thus a process of commonly forming the light emitting layer and other organic layers for the entire pixels through an open mask is formed or developed.

However, in case that the organic layer is commonly formed, a lateral leakage current may occur due to the organic layer commonly provided between adjacent pixels, and accordingly, color mixing and brightness defects may occur between the adjacent pixels.

### SUMMARY

Embodiments provide a display panel in which color mixing between adjacent pixels may be prevented and a decrease in brightness may be prevented by preventing a lateral leakage current from occurring between the adjacent pixels.

However, embodiments are not limited to those set forth herein. The above and other embodiments will become more apparent to one of ordinary skill in the art to which the disclosure pertains by referencing the detailed description of the disclosure given below.

According to an embodiment, a display device includes a base layer including a pixel area and a non-pixel area, a pixel defining layer disposed on the base layer and including a pixel opening corresponding to the pixel area, a light emitting unit disposed on the pixel defining layer, overlapping the pixel area, and including a charge generating layer, and a separation pattern disposed on the pixel defining layer and overlapping a valley area among the valley area and a non-valley area arranged on a virtual line surrounding the pixel opening, wherein the separation pattern includes a first pattern part protruding from an upper surface of the pixel defining layer to a first height, a second pattern part protruding from the upper surface of the pixel defining layer to a second height that is substantially same as the first height, and a third pattern part disposed between the first pattern part and the second pattern part and recessed from the first pattern part and the second pattern part toward the upper surface of the pixel defining layer, and the charge generating layer is disconnected on the third pattern part.

The third pattern part may protrude from the upper surface of the pixel defining layer to a third height that is smaller than the first height and the second height.

The separation pattern may be made of an organic photosensitive material.

The valley area may include a (1-1)^{th} valley part surrounding a portion of the pixel opening, a (1-2)^{th} valley part spaced farther from the pixel opening than the (1-1)^{th} valley part and having a shape corresponding to the (1-1)^{th} valley part, and an overlapping part disposed between the (1-1)^{th} valley part and the (1-2)^{th} valley part, and the first pattern part may overlap the (1-1)^{th} valley part, the second pattern part may overlap the (1-2)^{th} valley part, and the third pattern part may overlap the overlapping part.

The separation pattern may have a shape in which two protrusions protruding convexly from the upper surface of the pixel defining layer partially overlap the overlapping part on a cross section.

A lowest point of the third pattern part may be positioned at a center portion of the overlapping part.

The charge generating layer may be disconnected at a lowest point of the third pattern part, which is closest to the upper surface of the pixel defining layer.

The separation pattern may include a material that is cured in case that a light is irradiated.

The pixel area may include a first pixel area and a second pixel area spaced apart from the first pixel area, the pixel opening may include a first pixel opening corresponding to the first pixel area and a second pixel opening corresponding to the second pixel area, the non-valley area includes may include a first non-valley area disposed on a portion of a first virtual line surrounding the first pixel opening and a second non-valley area disposed on a portion of a second virtual line surrounding the second pixel opening, and the first non-valley area and the second non-valley area may not face each other.

The light emitting unit may include a first light emitting stack disposed on a lower surface of the charge generating layer and a second light emitting stack disposed on an upper surface of the charge generating layer, and each of the first light emitting stack and the second light emitting stack may include a light emitting layer that emits a light.

An angle formed between a normal line of an outer surface of the third pattern part and the upper surface of the pixel defining layer may increase as the angle is closer to a lowest point of the third pattern part.

The display device may further include a common electrode disposed on the light emitting unit and overlapping the pixel area and the non-pixel area, wherein the common electrode may not be disconnected on the third pattern part.

According to an embodiment, a display device includes a base layer including a pixel area and a non-pixel area, a pixel defining layer disposed on the base layer and including a pixel opening corresponding to the pixel area, and a light emitting unit disposed on the pixel defining layer, overlapping the pixel area, and including a charge generating layer, wherein a recessed part overlapping a valley area among the valley area and a non-valley area arranged on a virtual line surrounding the pixel opening is defined in the pixel defining layer, and the charge generating layer is disconnected at a lowest point of the recessed part closest to a lower surface of the pixel defining layer.

The pixel defining layer may include a material that is cured in case that a light is irradiated.

The pixel defining layer may include a first part of which a maximum height from the lower surface to an upper surface of the pixel defining layer is a first height, a second part of which a maximum height from the lower surface to the upper surface of the pixel defining layer is a second height that is substantially same as the first height, and a third part which is disposed between the first part and the second part and of which a maximum height from the lower surface to the upper surface of the pixel defining layer is a third height that is smaller than the first height and the second height.

An angle formed between a normal line of an outer surface of the recessed part and the lower surface of the pixel defining layer may increase as the angle is closer to the lowest point of the recessed part.

According to an embodiment, a method of manufacturing a display device includes forming a preliminary separation pattern layer on a preliminary display device including a base layer including a pixel area and a non-pixel area and a pixel defining layer which is disposed on the base layer and including a pixel opening corresponding to the pixel area, forming a separation pattern by exposing a light onto the preliminary separation pattern layer using a mask including a transmissive area, a non-transmissive area, and a semi-transmissive area, and forming a light emitting unit including a charge generating layer on the separation pattern, wherein the charge generating layer is disconnected on a portion of the separation pattern, which corresponds to the semi-transmissive area.

The separation pattern may include a first pattern part protruding from an upper surface of the pixel defining layer to a first height, a second pattern part protruding from the upper surface of the pixel defining layer to a second height that is substantially same as the first height, and a third pattern part disposed between the first pattern part and the second pattern part and recessed from the first pattern part and the second pattern part toward the upper surface of the pixel defining layer, the first pattern part and the second pattern part may correspond to the transmissive area, and the third pattern part may correspond to the semi-transmissive area, and the charge generating layer may be disconnected on the third pattern part.

The charge generating layer may be disconnected at a lowest point of the third pattern part, which is closest to the upper surface of the pixel defining layer.

The preliminary separation pattern layer may include a material that is cured in case that a light is irradiated.

### BRIEF DESCRIPTION OF THE FIGURES

The above and other objects and features of the disclosure will become apparent by describing in detail embodiments thereof with reference to the accompanying drawings.

FIG. 1 is a schematic perspective view of a coupled state of an electronic device according to an embodiment.

FIG. 2 is an exploded schematic perspective view of the electronic device according to an embodiment.

FIG. 3A is a schematic cross-sectional view of a display module according to an embodiment.

FIG. 3B is an enlarged schematic cross-sectional view of a portion of a display panel according to an embodiment.

FIG. 3C is an enlarged schematic cross-sectional view of a portion of a light emitting element according to an embodiment.

FIG. 3D is an enlarged schematic cross-sectional view of the portion of the light emitting element according to an embodiment.

FIG. 4A is an enlarged schematic plan view of the portion of the display panel according to an embodiment.

FIG. 4B is an enlarged schematic plan view of part BB′ of FIG. 4A according to an embodiment.

FIG. 5A is a schematic cross-sectional view along line I-I′ of FIG. 4B according to an embodiment.

FIG. 5B is an enlarged schematic cross-sectional view of part CC′ of FIG. 5A according to an embodiment.

FIG. 6 is a schematic cross-sectional view along line I-I′ of FIG. 4B according to an embodiment.

FIG. 7 is an enlarged schematic plan view of part BB′ of FIG. 4A according to an embodiment.

FIG. 8 is a schematic cross-sectional view along line II-II of FIG. 7 according to an embodiment.

FIG. 9 is an enlarged schematic cross-sectional view of part DD′ of FIG. 8 according to an embodiment.

FIGS. 10A, 10B, 10C, and 10D are schematic cross-sectional views illustrating a portion of a method of manufacturing a display device according to an embodiment.

FIGS. 11A, 11B, 11C, and 11D are schematic cross-sectional views illustrating a portion of the method of manufacturing the display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, an embodiment will be described with reference to the accompanying drawings.

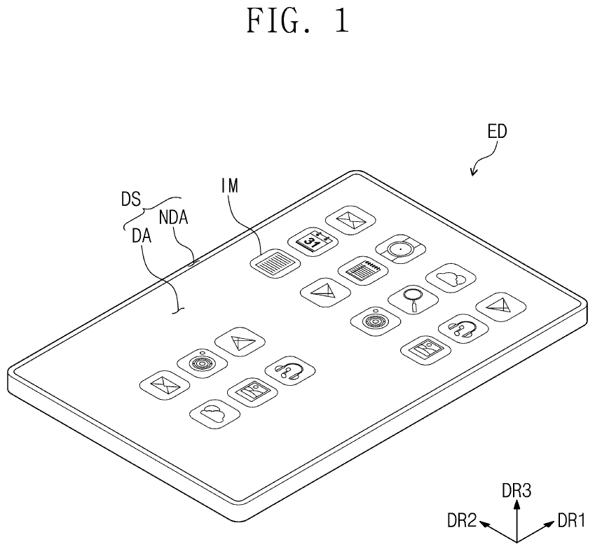

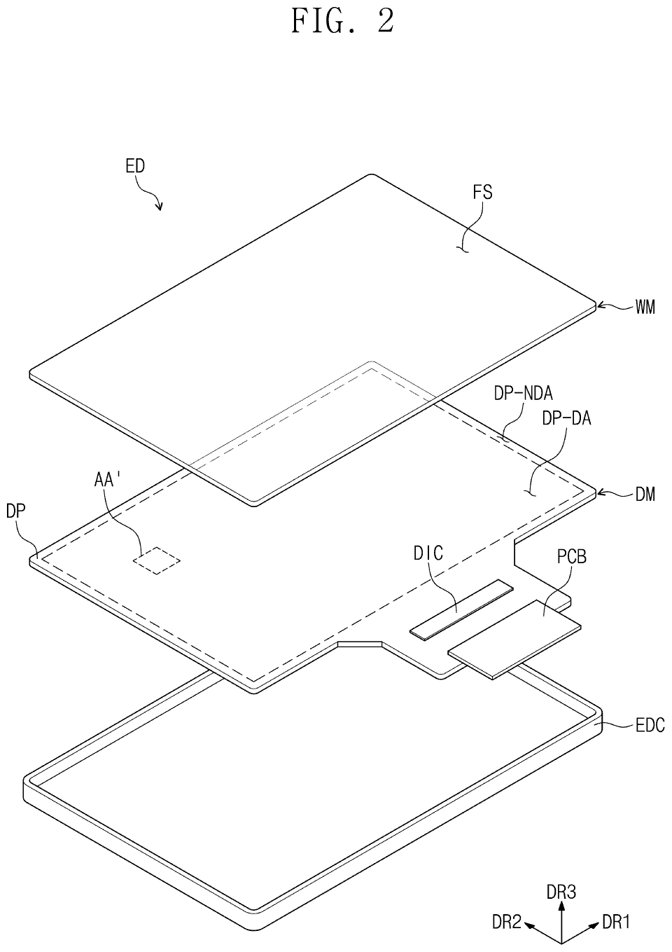

FIG. 1 is a schematic perspective view of a coupled state of an electronic device according to an embodiment. FIG. 2 is an exploded schematic perspective view of the electronic device according to an embodiment.

Referring to FIG. 1, an electronic device ED may be a device that is activated according to an electric signal. The electronic device ED may display an image IM and sense an external input. The electronic device ED may include an embodiment. For example, the electronic device ED may include a tablet personal computer (PC), a laptop, a computer, a smart phone, a television, or the like. In an embodiment, the electronic device ED is illustratively illustrated as the tablet PC. However, embodiments are not limited thereto, and the electronic device according to an embodiment may be a smart phone or the electronic device according to an embodiment may be a large-sized display device such as a laptop, a monitor, or a television.

The electronic device ED may display an image IM in a third direction DR3 on a display surface DS parallel to a first direction DR1 and a second direction DR2. The display surface DS on which the image IM is displayed may correspond to a front surface of the electronic device ED and correspond to a front surface FS of a window WM. Hereinafter, the same reference numeral will be used for the display surface and the front surface of the electronic device ED and the front surface of the window WM. The image IM may include a still image as well as a dynamic image. In FIG. 1, icons are illustrated as an example of the image IM.

In an embodiment, a front surface (or an upper surface) and a rear surface (or a lower surface) of each member may be defined with respect to a direction in which the image IM is displayed. The front surface and the rear surface may be opposite to each other in the third direction DR3, and a normal direction of each of the front surface and the rear surface may be parallel to the third direction DR3. A separation distance between the front surface and the rear surface in the third direction DR3 may correspond to a thickness of the electronic device ED in the third direction DR3. For example, directions indicated by the first to third directions DR1, DR2, and DR3 are relative concepts and may be changed to other directions. Hereinafter, the first to third directions refer to the same reference numerals as those of the directions indicated by the first to third directions DR1, DR2, and DR3, respectively. Further, in the description, the wording “on a plane” or “in plan view” may mean a state in which a component is viewed on a plane defined by the first direction DR1 and the second direction DR2.

The electronic device ED according to an embodiment may sense an input of a user, which is applied from the outside. The input of the user may include various types of external inputs such as a portion of a body of the user, light, heat, or pressure. The input of the user may be provided in various forms, and the electronic device ED may sense the input of the user applied to a side surface or a rear surface of the electronic device ED according to a structure of the electronic device ED, but embodiments are not limited thereto.

As illustrated in FIG. 2, the electronic device ED may include the window WM, a display module DM, and an external case EDC. In an embodiment, the window WM and the external case EDC may be coupled to each other to constitute an exterior of the electronic device ED. In an embodiment, the external case EDC, the display module DM, and the window WM may be sequentially laminated in the third direction DR3.

The window WM may include an optically transparent material. The window WM may include an insulating panel. For example, the window WM may be made of glass, plastic, or a combination thereof.

As described above, the front surface FS of the window WM may define the front surface of the electronic device ED.

The window WM may include a bezel area and a transmissive area. The transmissive area may be an optically transparent area. For example, the transmissive area may be an area having a visible light transmittance of about 90% or more.

The bezel area may be an area having relatively low light transmittance compared to the transmissive area. The bezel area may define a shape of the transmissive area. The bezel area may be adjacent to the transmissive area and surround the transmissive area. The bezel area may have a selected color. The bezel area may overlap a non-display area DP-NDA of a display panel DP, which will be described below. The bezel area may cover the non-display area DP-NDA of the display panel DP and prevent the non-display area DP-NDA from being visually recognized from the outside. For example, this is illustratively described, and in the window WM according to an embodiment, the bezel area may also be omitted.

The display module DM may include at least the display panel DP. Although FIG. 2 illustrates only the display panel DP among laminated structures of the display module DM, substantially, the display module DM may further include components arranged on and under the display panel DP. The laminated structure of the display module DM will be described below.

The display panel DP may include a display area DP-DA corresponding to a display area DA (see FIG. 1) of the electronic device ED and the non-display area DP-NDA corresponding to a non-display area NDA (see FIG. 1) of the electronic device ED. In the description, an expression “an area/part and an area/part correspond to each other” means that the area/part and the area/part overlap each other and is not limited to the same area. The display module DM may include a driving chip DIC disposed on the non-display area DP-NDA. The display module DM may further include a printed circuit board PCB coupled to the non-display area DP-NDA. The printed circuit board PCB may be electrically connected to pads arranged in the non-display area DP-NDA of the display panel DP through an anisotropic conductive adhesive layer.

The driving chip DIC may include driving elements, for example, data driving circuits, for driving pixels of the display panel DP. Although a structure, in which the driving chip DIC is mounted on the display panel DP, is illustrated in FIG. 2, embodiments are not limited thereto. For example, the driving chip DIC may be mounted on the printed circuit board PCB.

The external case EDC may accommodate the display module DM and may be coupled to the window WM. The external case EDC may protect components accommodated inside the external case EDC, such as the display module DM.

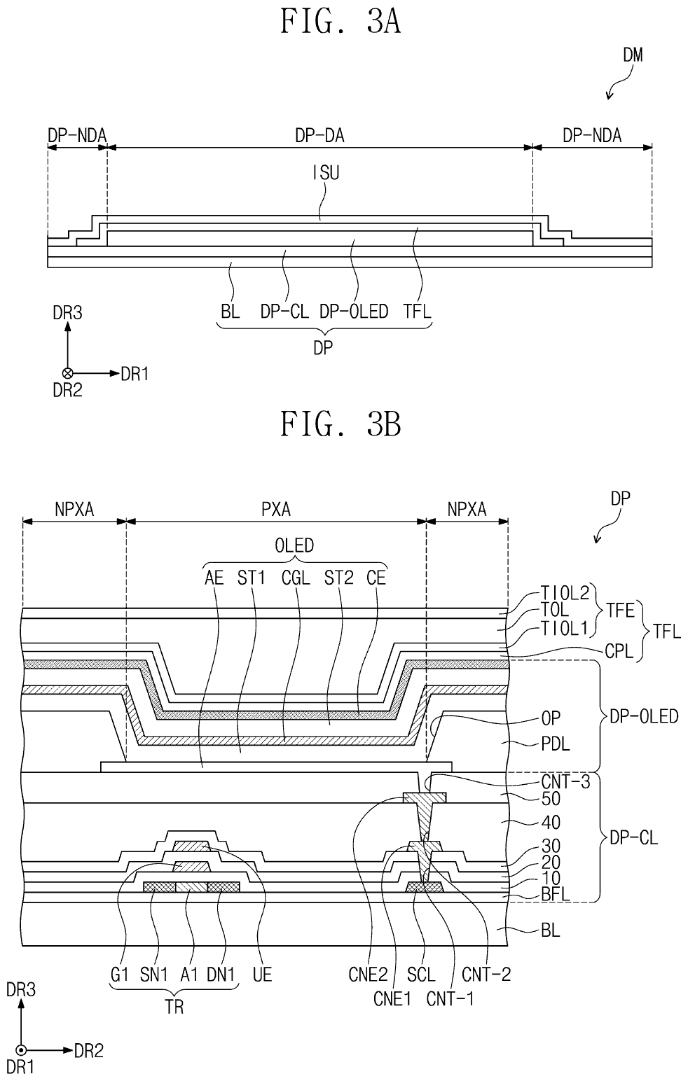

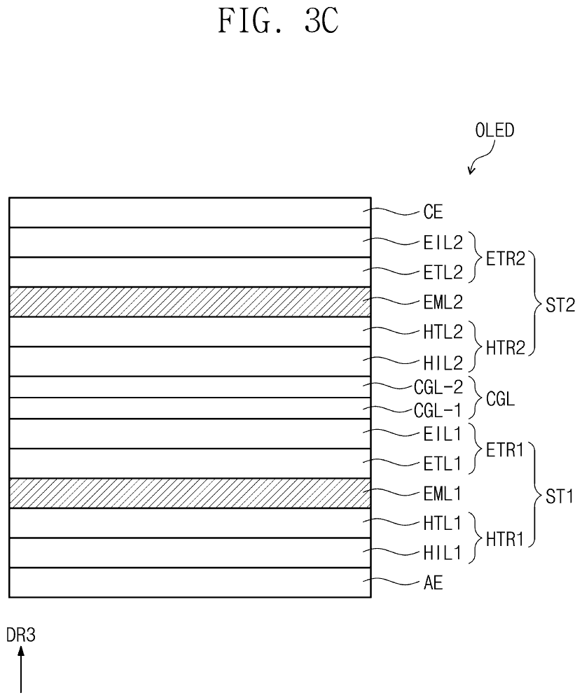

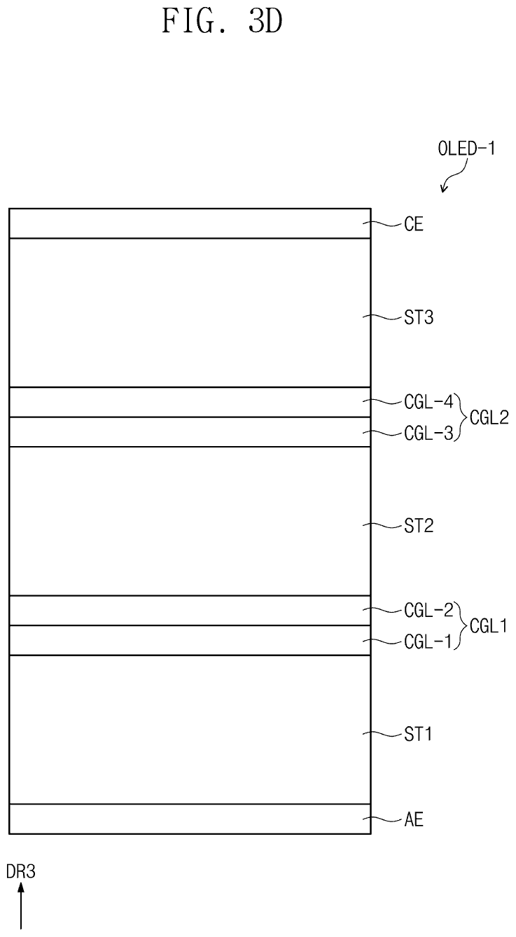

FIG. 3A is a schematic cross-sectional view of a display module according to an embodiment. FIG. 3B is an enlarged schematic cross-sectional view of a portion of a display panel according to an embodiment. FIGS. 3C and 3D are enlarged schematic cross-sectional view of a portion of a light emitting element according to an embodiment. FIG. 3B illustratively illustrates a light emitting element OLED and a transistor TR included in one pixel included in the display panel DP of an embodiment.

Referring to FIG. 3A, the display module DM may include the display panel DP and an input sensing unit ISU. The display panel DP may be a component that substantially generates the image IM (see FIG. 1). The image IM (see FIG. 1) generated by the display panel DP may be visually recognized by the user from the outside through the display area DA (see FIG. 1).

The display panel DP may be a light emitting display panel, but embodiments are not particularly limited thereto. For example, the display panel DP may be an organic light emitting display panel or inorganic light emitting display panel. The organic light emitting display panel may be a display panel in which a light emitting layer includes an organic light emitting material. The inorganic light emitting display panel may be a display panel in which the light emitting layer includes a quantum dot, a quantum rod, or a micro light emitting diode (LED). Hereinafter, the display panel DP is described as the organic light emitting display panel.

The input sensing unit ISU may be disposed on the display panel DP. The input sensing unit ISU may sense an external input applied from the outside. The external input may include various types of inputs provided from the outside of the electronic device ED (see FIG. 1). The inputs applied from the outside may be provided in various forms. For example, the external input may include a contact by the portion of the body of the user, such as a hand, and an external input (e.g., hovering) applied to be close to the electronic device ED (see FIG. 1) or adjacent to the electronic device ED at a selected distance. Further, the external input may have various forms such as force, pressure, and light, and embodiments are not limited to an embodiment.

The input sensing unit ISU may be formed on the display panel DP through a continuous process. For example, the input sensing unit ISU may be disposed (e.g., directly disposed) on the display panel DP. For example, in the description, the wording “component B is directly disposed on component A” may mean that no third component is disposed between component A and component B. For example, no adhesive layer may be disposed between the input sensing unit ISU and the display panel DP.

The display panel DP may include a base layer BL, and a circuit element layer DP-CL, a display element layer DP-OLED, and an upper insulating layer TFL which are arranged on the base layer BL.

The base layer BL may provide a base surface on which the circuit element layer DP-CL, the display element layer DP-OLED, and the upper insulating layer TFL are arranged. The base layer BL may be a rigid substrate or a flexible substrate that may be bent, folded, and rolled. The base layer BL may be a glass substrate, a metal substrate, a polymer substrate, or the like. However, embodiments are not limited thereto, and the base layer BL may include an inorganic layer, an organic layer, or a composite material layer.

The base layer BL may have a multi-layer structure. For example, the base layer BL may include a first synthetic resin layer, a multi-layer or single-layer inorganic layer, and a second synthetic resin layer disposed on the multi-layer or single-layer inorganic layer. Each of the first and second synthetic resin layers may include a polyimide-based resin, but embodiments are not particularly limited thereto.

The circuit element layer DP-CL may be disposed on the base layer BL. The circuit element layer DP-CL may include insulating layers, conductive layers, and a semiconductor layer. The conductive layers of the circuit element layer DP-CL may constitute signal lines or a control circuit of the pixel.

The display element layer DP-OLED may be disposed on the circuit element layer DP-CL. The display element layer DP-OLED may include light emitting elements. The display element layer DP-OLED may include, for example, organic light emitting elements. However, this is illustrative, and the display element layer DP-OLED according to an embodiment may include inorganic light emitting elements, organic-inorganic light emitting elements, or liquid crystal layers.

The upper insulating layer TFL may include a capping layer and a thin film encapsulation layer, which will be described below. The upper insulating layer TFL may include an organic layer and inorganic layers that seal the organic layer.

The upper insulating layer TFL may be disposed on the display element layer DP-OLED and may protect the display element layer DP-OLED from foreign substances such as moisture, oxygen, and dust particles. The upper insulating layer TFL may seal the display element layer DP-OLED to block moisture and oxygen flowing into the display element layer DP-OLED. The upper insulating layer TFL may include at least one inorganic layer. The upper insulating layer TFL may include the organic layer and the inorganic layers that seal the organic layer. The upper insulating layer TFL may include a laminated structure of an inorganic layer/organic layer/inorganic layer in this order.

The input sensing unit ISU may be disposed on the upper insulating layer TFL. The input sensing unit ISU may be formed on the upper insulating layer TFL through a continuous process. The input sensing unit ISU may be disposed (e.g., directly disposed) on the display panel DP. For example, no separate adhesive member may be disposed between the input sensing unit ISU and the display panel DP. The input sensing unit ISU may be arranged in contact with the inorganic layer disposed on uppermost side of the upper insulating layer TFL.

For example, the display module DM according to an embodiment may further include a protection member disposed on a lower surface of the display panel DP and a reflection preventing member disposed on an upper surface of the input sensing unit ISU. The reflection preventing member may reduce a reflectance of an external light. The reflection preventing member may be disposed (e.g., directly disposed) on the input sensing unit ISU through a continuous process.

The reflection preventing member may include a light shielding pattern that overlaps a reflective structure disposed below the reflection preventing member. The reflection preventing member may further include a color filter. The color filter may be disposed between the light shielding patterns and may include a first color filter, a second color filter, and a third color filter corresponding to a first color pixel, a second color pixel, and a third color pixel.

As illustrated in FIG. 3A, the display panel DP may be divided into the display area DP-DA and the non-display area DP-NDA in plan view or on a plane. The display area DP-DA of the display panel DP may be an area on which an image is displayed, and the non-display area DP-NDA may be an area in which a driving circuit, a driving wiring line, or the like is disposed. Light emitting elements of the pixels may be arranged in the display area DP-DA. The display area DP-DA may overlap at least a portion of the transmissive area of the window WM (see FIG. 2), and the non-display area DP-NDA may be covered by the bezel area of the window WM. The display area DP-DA and the non-display area DP-NDA of the display panel DP may correspond to the display area DA and the non-display area NDA of the electronic device ED illustrated in FIG. 1, respectively.

Hereinafter, configurations of the circuit element layer DP-CL, the display element layer DP-OLED, and the upper insulating layer TFL will be described in detail through FIGS. 3B and 3C.

Referring to FIG. 3B, the circuit element layer DP-CL may include at least one insulating layer and a circuit element. The circuit element may include the signal line, the driving circuit of the pixel, and the like. The circuit element layer DP-CL may be formed through a process of forming the insulating layer, the semiconductor layer, and the conductive layer by coating, deposition, or the like and a process of patterning the insulating layer, the semiconductor layer, and the conductive layer by a photolithography process.

A buffer layer BFL may include at least one laminated inorganic layer. A semiconductor pattern may be disposed on the buffer layer BFL. The buffer layer BFL may improve a coupling force between the base layer BL and the semiconductor pattern.

The semiconductor pattern may include polysilicon. However, embodiments are not limited thereto, and the semiconductor pattern may include amorphous silicon or metal oxide. FIG. 3B illustrates a portion of the semiconductor pattern, and the semiconductor pattern may be further disposed in another area of the pixel in plan view or on a plane. The semiconductor pattern may be disposed in a specific rule across the pixels.

The semiconductor pattern may have different electrical properties according to whether the semiconductor pattern is doped. The semiconductor pattern may include a first area A1 having low doping concentration and low conductivity and second areas SN1 and DN1 having relatively high doping concentration and relatively high conductivity. The second area SN1 may be disposed on a side of the first area A1, and the second area DN1 may be disposed on the other side of the first area A1. The second areas SN1 and DN1 may be doped with an N-type dopant or a P-type dopant. A P-type transistor may include a doped area doped with the P-type dopant. The first area A1 may be a non-doped area or may be doped at a lower concentration than that of the second areas SN1 and DN1.

The second areas SN1 and DN1 may function as electrodes or signal lines. The second area (e.g., single second area) SN1 may correspond to a source of the transistor TR, and the second area DN1 may correspond to a drain thereof. FIG. 3B illustrates a portion of a connection signal line SCL formed from the semiconductor pattern. For example, the connection signal line SCL may be connected to the drain of the transistor TR in plan view or on a plane.

A first insulating layer 10 may be disposed on the buffer layer BFL. The first insulating layer 10 may commonly overlap the pixels arranged in the display area DP-DA and covers the semiconductor pattern. The first insulating layer 10 may be an inorganic layer and/or an organic layer and may have a single-layer structure or a multi-layer structure. The first insulating layer 10 may include at least one of an aluminum oxide, a titanium oxide, a silicon oxide, a silicon oxy nitride, a zirconium oxide, and a hafnium oxide. An insulating layer of the circuit element layer DP-CL, which will be described below, as well as the first insulating layer 10 may be an inorganic layer and/or an organic layer and may have a single-layer structure or a multi-layer structure.

A gate G1 may be disposed on the first insulating layer 10. The gate G1 may be a portion of a metal pattern. The gate G1 may overlap the first area A1. The gate G1 may function as a mask in a process of doping the semiconductor pattern.

A second insulating layer 20 may be disposed on the first insulating layer 10 and cover the gate G1. The second insulating layer 20 may commonly overlap the pixels. An upper electrode UE may be disposed on the second insulating layer 20. The upper electrode UE may overlap the gate G1. The upper electrode UE may include a multi-layer metal layer. In an embodiment, the upper electrode UE may be omitted.

A third insulating layer 30 may be disposed on the second insulating layer 20 and cover the upper electrode UE. A first connection electrode CNE1 may be disposed on the third insulating layer 30. The first connection electrode CNE1 may be connected to the connection signal line SCL through a contact hole CNT-1 passing through the first to third insulating layers 10 to 30.

A fourth insulating layer 40 may be disposed on the third insulating layer 30, and a fifth insulating layer 50 may be disposed on the fourth insulating layer 40. The fourth insulating layer 40 may be an organic layer. A second connection electrode CNE2 may be disposed on the fourth insulating layer 40. The second connection electrode CNE2 may be connected to the first connection electrode CNE1 through a contact hole CNT-2 passing through the fourth insulating layer 40.

The fifth insulating layer 50 may be disposed on the fourth insulating layer 40 and cover the second connection electrode CNE2. The fifth insulating layer 50 may be an organic layer.

The light emitting element OLED may be disposed on the fifth insulating layer 50. A first electrode AE may be disposed on the fifth insulating layer 50. The first electrode AE may be connected to the second connection electrode CNE2 through a contact hole CNT-3 passing through the fifth insulating layer 50. A pixel opening OP may be formed (or defined) in a pixel defining layer PDL, and at least a portion of the first electrode AE may be exposed through the pixel defining layer PDL. The pixel defining layer PDL may be an organic layer.

The display area DP-DA may include a pixel area PXA and a non-pixel area NPXA adjacent to the pixel area PXA. The non-pixel area NPXA may surround the pixel area PXA. In an embodiment, the pixel area PXA may be formed (or defined) to correspond to a partial area of the first electrode AE, which is exposed by the pixel opening OP.

Referring to FIG. 3C, the light emitting element OLED may include the first electrode AE, a first light emitting stack ST1, a charge generating layer CGL, a second light emitting stack ST2, and a second electrode CE (or a common electrode) that are sequentially laminated in the third direction DR3. The light emitting element OLED may be a light emitting element having a tandem structure including the light emitting stacks ST1 and ST2 including light emitting layers.

The first light emitting stack ST1 may include a first light emitting layer EML1 and a first hole control layer HTR1 and a first electron control layer ETR1 with the first light emitting layer EML1 interposed therebetween.

The first hole control layer HTR1 may include at least one of a first hole injection layer HIL1 and a first hole transport layer HTL1. The first hole transport layer HTL1 may include at least one of a first hole buffer layer and a first electron blocking layer.

The first electron control layer ETR1 may include at least one of a first electron injection layer EIL1 and a first electron transport layer ETL1. The first electron control layer ETR1 may further include a first hole blocking layer.

The second light emitting stack ST2 may include a second light emitting layer EML2 and a second hole control layer HTR2 and a second electron control layer ETR2 with the second light emitting layer EML2 interposed therebetween.

The second hole control layer HTR2 may include at least one of a second hole injection layer HIL2 and a second hole transport layer HTL2. The second electron control layer ETR2 may include at least one of a second electron injection layer EIL2 and a second electron transport layer ETL2. The descriptions of the first hole control layer HTR1 and the first electron control layer ETR1 may be equally (or similarly) applied to descriptions of the second hole control layer HTR2 and the second electron control layer ETR2.

In an embodiment, all lights emitted from the light emitting stacks ST1 and ST2 may have the same wavelength. For example, lights emitted from the light emitting stacks ST1 and ST2 may be a blue light. However, embodiments are not limited thereto, and wavelength ranges of the lights emitted from the light emitting stacks ST1 and ST2 may be different from each other. For example, at least one of the light emitting stacks ST1 and ST2 may emit a blue light, and the other one thereof may emit a green light. The light emitting element OLED including the light emitting stacks ST1 and ST2 that emit lights having different wavelength ranges may emit a white light.

The charge generating layer CGL may be disposed between the first light emitting stack ST1 and the second light emitting stack ST2. In case that a voltage is applied, the charge generating layer CGL may generate charges (electrons and holes) by forming a complex through an oxidation-reduction reaction. Further, the charge generating layer CGL may provide the generated charges to the light emitting stacks ST1 and ST2. The charge generating layer CGL may double current efficiency generated in the light emitting stacks ST1 and ST2 and may function to balance the charges between the first light emitting stack ST1 and the second light emitting stack ST2.

In more detail, the charge generating layer CGL may have a layer structure in which a lower charge generating layer CGL-1 and an upper charge generating layer CGL-2 are bonded to each other. The lower charge generating layer CGL-1 may be an n-type charge generating layer that is disposed adjacent to the first light emitting stack ST1 and provides electrons to the first light emitting stack ST1. The lower charge generating layer CGL-1 may include an aryl amine-based organic compound.

The upper charge generating layer CGL-2 may be an p-type charge generating layer that is disposed adjacent to the second light emitting stack ST2 and provides holes to the second light emitting stack ST2. The upper charge generating layer CGL-2 may include a charge generating compound made of a metal, a metal oxide, a carbide, a fluoride, or a mixture thereof.

A buffer layer may be further disposed between the lower charge generating layer CGL-1 and the upper charge generating layer CGL-2.

According to an embodiment, the first light emitting stack ST1, the charge generating layer CGL, and the second light emitting stack ST2 may be commonly formed in the pixels using an open mask. However, embodiments are not limited thereto, and at least one of the first and second hole control layers HTR1 and HTR2, the first and second light emitting layers EML1 and EML2, and the first and second electron control layers ETR1 and ETR2 may be patterned and formed through the mask. For example, the first and second light emitting layers EML1 and EML2 may be arranged in an area corresponding to the pixel opening OP. For example, the first and second light emitting layers EML1 and EML2 may be separately formed in the pixels.

The second electrode CE may be disposed on the second light emitting stack ST2. The second electrode CE may have an integral shape and may be disposed in the pixels in common.

Referring back to FIG. 3B, the upper insulating layer TFL may be disposed on the display element layer DP-OLED and include thin films. According to an embodiment, the upper insulating layer TFL may include a capping layer CPL and an encapsulation layer TFE disposed on the capping layer CPL. The capping layer CPL may be disposed on the second electrode CE and may contact the second electrode CE. The capping layer CPL may include an organic material.

The encapsulation layer TFE may include a first inorganic encapsulation layer TIOL1, an organic encapsulation layer TOL disposed on the first inorganic encapsulation layer TIOL1, and a second inorganic encapsulation layer TIOL2 disposed on the organic encapsulation layer TOL. The first inorganic encapsulation layer TIOL1 and the second inorganic encapsulation layer TIOL2 may protect the display element layer DP-OLED from moisture/oxygen, and the organic encapsulation layer TOL may protect the display element layer DP-OLED from foreign substances such as dust particles.

Referring to FIG. 3D, a light emitting element OLED-1 according to an embodiment may include the first electrode AE, the first light emitting stack ST1, a first charge generating layer CGL1, the second light emitting stack ST2, a second charge generating layer CGL2, a third light emitting stack ST3, and the second electrode CE. In an embodiment, the light emitting element OLED-1 may include the three light emitting stacks ST1, ST2, and ST3 and the two charge generating layers CGL1 and CGL2 arranged between the adjacent light emitting stacks ST1, ST2, and ST3. The same/similar reference numerals are used for the same/similar components described in FIGS. 3B and 3C, and a duplicated description thereof will be omitted.

The third light emitting stack ST3 may have a structure similar to the first and second light emitting stacks ST1 and ST2 described above in FIG. 3C. The third light emitting stack ST3 may include a third hole control layer, a third light emitting layer, and a third electron control layer that are sequentially laminated on the second charge generating layer CGL2 (see FIG. 3C) in the third direction DR3.

Further, the first and second charge generating layers CGL1 and CGL2 may have a structure similar to the charge generating layer CGL described above in FIG. 3C. The first charge generating layer CGL1 may have a layer structure in which a first lower charge generating layer CGL-1 and a first upper charge generating layer CGL-2 are bonded to each other, and the second charge generating layer CGL2 may have a layer structure in which a second lower charge generating layer CGL-3 and a second upper charge generating layer CGL-4 are bonded to each other.

For example, the numbers of the light emitting stacks ST1, ST2, and ST3 and the charge generating layers CGL1 and CGL2 are not limited to those illustrated in FIGS. 3C and 3D, and the light emitting element OLED-1 may also include four or more light emitting stacks and three or more charge generating layers arranged therebetween.

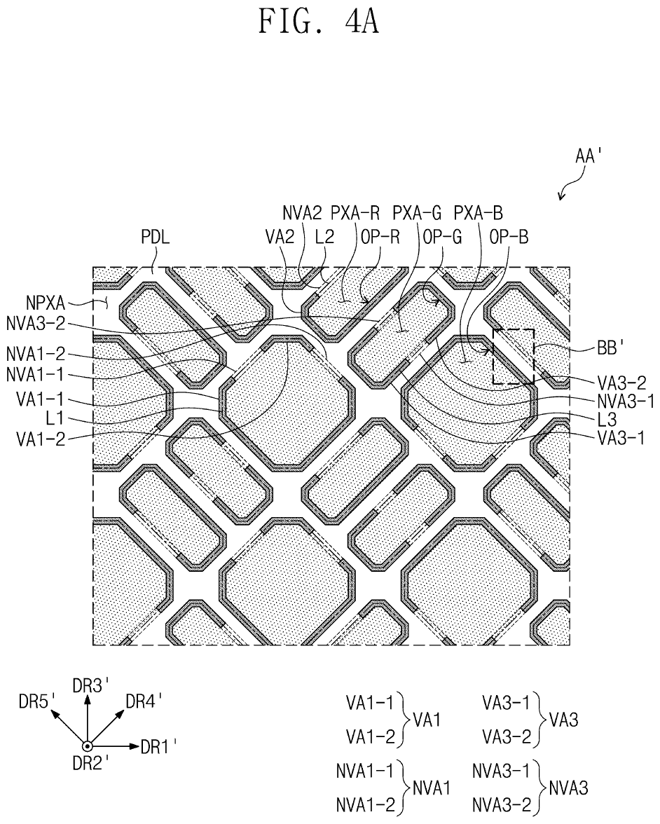

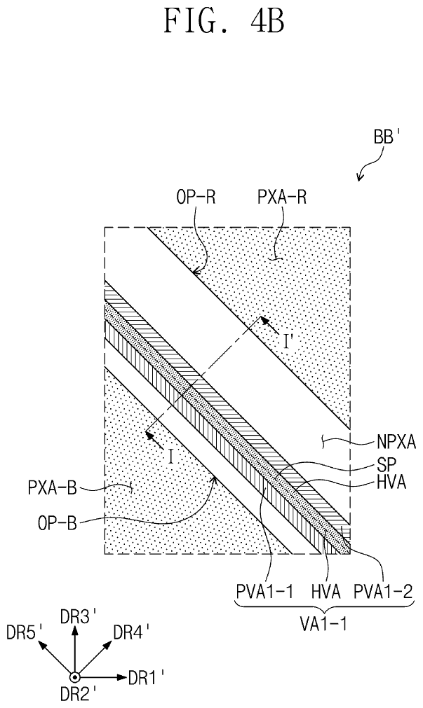

FIG. 4A is an enlarged schematic plan view of the portion of the display panel according to an embodiment. FIG. 4A is an enlarged schematic view of arrangement of the pixels and valley areas VA1, VA2, and VA3 and non-valley areas NVA1, NVA2, and NVA3 defined adjacent thereto in area AA′ inside the display panel DP illustrated in FIG. 2.

Referring to FIG. 4A, in the display module DM (see FIG. 2) of an embodiment, the display area DP-DA (see FIG. 2) may include pixel areas PXA-B, PXA-R, and PXA-G and the non-pixel area NPXA surrounding the pixel areas PXA-B, PXA-R, and PXA-G. In the description, the base layer BL (see FIG. 3B) of the display panel DP may include the pixel areas PXA-B, PXA-R, and PXA-G and the non-pixel area NPXA, and the remaining components of the display panel DP disposed on the base layer BL (see FIG. 3B) may overlap the pixel areas PXA-B, PXA-R, and PXA-G and/or the non-pixel area NPXA.

The pixel areas PXA-B, PXA-R, and PXA-G may include the first pixel area PXA-B, the second pixel area PXA-R, and the third pixel area PXA-G. The first pixel area PXA-B, the second pixel area PXA-R, and the third pixel area PXA-G may emit lights having different wavelengths. The first pixel area PXA-B may emit a first light having a blue wavelength, the second pixel area PXA-R may emit a second light having a red wavelength, and the third pixel area PXA-G may emit a third light having a green wavelength.

The first pixel areas PXA-B may be arranged in a first direction DR1′ and a third direction DRY. The first pixel areas PXA-B may form pixel rows arranged in the first direction DR1′. The pixel rows may be spaced apart from each other in the third direction DRY. The second pixel areas PXA-R may be arranged between the first pixel areas PXA-B in a fifth direction DR5′ or a fourth direction DR4′. The third pixel areas PXA-G may be arranged between the first pixel areas PXA-B in the fifth direction DR5′ or the fourth direction DR4′.

For example, the first to fourth directions DR1′, DR2′, DRY, and DR4′ may represent directions different from the first to third directions DR1, DR2, and DR3 described in FIGS. 1 to 3D. The first to fourth directions DR1′, DR2′, DRY, and DR4′ are not absolute directions, but are relative directions for description, and may be interchanged.

Each of the pixel areas PXA-B, PXA-R, and PXA-G may be an area divided by the pixel defining layer PDL. The non-pixel area NPXA may be an area between the adjacent pixel areas PXA-B, PXA-R, and PXA-G and may be an area corresponding to the pixel defining layer PDL.

In the pixel defining layer PDL, first pixel openings OP-B corresponding to the first pixel areas PXA-B, second pixel openings OP-R corresponding to the second pixel areas PXA-R, and third pixel openings OP-G corresponding to the third pixel areas PXA-G may be defined.

Each of the first pixel areas PXA-B may correspond to the first electrode AE (see FIG. 3B) exposed from the pixel defining layer PDL by the corresponding first pixel opening OP-B. Each of the second pixel areas PXA-R may correspond to the first electrode AE (see FIG. 3B) exposed from the pixel defining layer PDL by the corresponding second pixel opening OP-R. Each of the third pixel areas PXA-G may correspond to the first electrode AE (see FIG. 3B) exposed from the pixel defining layer PDL by the corresponding third pixel opening OP-G.

The first to third pixel areas PXA-B, PXA-R, and PXA-G may have different areas according to a wavelength of the emitted light. For example, the first pixel area PXA-B that emits a first light may have the largest area. The second pixel area PXA-R that emits the second light and the third pixel area PXA-G that emits the third light may have substantially the same area. However, embodiments are not limited thereto, and the first to third pixel areas PXA-B, PXA-R, and PXA-G may have the same area or the first to third pixel areas PXA-B, PXA-R, and PXA-G may be defined in an area ratio that is different from that illustrated in FIG. 4A. In another example, the first to third pixel areas PXA-B, PXA-R, and PXA-G may emit a light having other colors in addition to the light having the green wavelength, the light having the blue wavelength, and the light having the red wavelength.

Each of the first to third pixel areas PXA-B, PXA-R, and PXA-G may have a rectangular shape having rounded corners in plan view or on a plane. However, the shapes of the first to third pixel areas PXA-B, PXA-R, and PXA-G are illustratively illustrated, and the first to third pixel areas PXA-B, PXA-R, and PXA-G may be modified into various shapes as needed.

In an embodiment, first virtual lines L1, second virtual lines L2, and third virtual lines L3 may be defined in the pixel defining layer PDL. Each of the first virtual lines L1 may be formed (or defined) as a line that encloses (e.g., completely encloses) the corresponding first pixel opening OP-B. Each of the second virtual lines L2 may be formed (or defined) as a line that encloses (e.g., completely encloses) the corresponding second pixel opening OP-R. Each of the third virtual lines L3 may be formed (or defined) as a line that encloses (e.g., completely encloses) the corresponding third pixel opening OP-G.

The pixel defining layer PDL may include at least one first valley area VA1 and at least one first non-valley area NVA1 arranged on a first virtual line (e.g., single first virtual line) L1, at least one second valley area VA2 and at least one second non-valley area NVA2 arranged on a second virtual line (e.g., single second virtual line) L2, and at least one third valley area VA3 and at least one third non-valley area NVA3 arranged on a third virtual line (e.g., single third virtual line) L3.

In an embodiment, the first valley areas VA1 may be provided on the first virtual line L1. The first valley area VA1 may include a (1-1)^{th} valley area VA1-1 and a (1-2)^{th} valley area VA1-2 on the first virtual line L1. The (1-1)^{th} valley area VA1-1 and the (1-2)^{th} valley area VA1-2 may be spaced apart from each other. The (1-1)^{th} valley area VA1-1 and the (1-2)^{th} valley area VA1-2 may surround the remaining part of an exterior of the first pixel area PXA-B except for a (1-1)^{th} non-valley area NVA1-1 and a (1-2)^{th} non-valley area NVA1-2. The (1-1)^{th} valley area VA1-1 and the (1-2)^{th} valley area VA1-2 may face each other in the third direction DRY.

In an embodiment, first non-valley areas NVA1 may be provided on the first virtual line L1, and the first non-valley areas NVA1 may include the (1-1)^{th} non-valley area NVA1-1 and the (1-2)^{th} non-valley area NVA1-2.

The (1-1)^{th} non-valley area NVA1-1 and the (1-2)^{th} non-valley area NVA1-2 may be arranged between the first valley areas VA1 on the first virtual line L1. The (1-1)^{th} non-valley area NVA1-1 may extend parallel to the fourth direction DR4′. The (1-2)^{th} non-valley area NVA1-2 may extend parallel to the fifth direction DR5′.

In an embodiment, the second virtual line L2 may surround the second pixel area PXA-R. The second valley area VA2 may be provided on the second virtual line L2. The second valley area VA2 may surround a long side (e.g., single long side) of the second pixel area PXA-R extending in the fourth direction DR4′ or the fifth direction DR5′ and two short sides of the second pixel area PXA-R extending in the fifth direction DR5′ or the fourth direction DR4′.

In an embodiment, the second non-valley area NVA2 may be provided on the second virtual line L2. The second non-valley area NVA2 may be disposed on a long side (e.g., single long side) of the second pixel area PXA-R, which extends in the fourth direction DR4′ or the fifth direction DR5′. The second non-valley area NVA2 may be disposed on a center portion of the long side of the second pixel area PXA-R, which extends in the fourth direction DR4′ or the fifth direction DR5′.

The second non-valley area NVA2 may face the adjacent first valley area VA1 in the fourth direction DR4′ or the fifth direction DR5′. The second non-valley area NVA2 may not face the first non-valley area NVA1 in the fourth direction DR4′ or the fifth direction DR5′. The second non-valley area NVA2 may be disposed adjacent to the first pixel area PXA-B. The second non-valley area NVA2 may be disposed on a long side adjacent to the first pixel area PXA-B among the long sides of the second pixel area PXA-R.

In an embodiment, the third valley areas VA3 may be provided on the third virtual line L3. The third valley area VA3 may include a (3-1)^{th} valley area VA3-1 and a (3-2)^{th} valley area VA3-2 on the third virtual line L3. The (3-1)^{th} and (3-2)^{th} valley areas VA3-1 and VA3-2 may be spaced apart from each other.

In an embodiment, the (3-1)^{th} valley area VA3-1 may surround a first short side of the third pixel area PXA-G, a portion of a first long side adjacent to the first short side, and a portion of a second long side adjacent to the first short side. The (3-2)^{th} valley area VA3-2 may surround a second short side of the third pixel area PXA-G, a portion of the first long side adjacent to the second short side, and a portion of the second long side adjacent to the second short side.

In an embodiment, third non-valley areas NVA3 may be provided on the third virtual line L3, and the third non-valley areas NVA3 may include a (3-1)^{th} non-valley area NVA3-1 and a (3-2)^{th} non-valley area NVA3-2.

Each of the (3-1)^{th} and (3-2)^{th} non-valley areas NVA3-1 and NVA3-2 may extend in the fourth direction DR4′ or the fifth direction DR5′. The (3-1)^{th} and (3-2)^{th} non-valley areas NVA3-1 and NVA3-2 may be arranged adjacent to the first and second long sides of the third pixel area PXA-G. The (3-1)^{th} non-valley area NVA3-1 may face the adjacent first valley area VA1 in the fourth direction DR4′ or the fifth direction DR5′. The (3-2)^{th} valley area VA3-2 may face the adjacent second valley area VA2 in the fourth direction DR4′ or the fifth direction DR5′.

In an embodiment, a length of the (3-1)^{th} non-valley area NVA3-1 in the fourth direction DR4′ or the fifth direction DR5′ may be substantially the same as a length of the (3-2)^{th} non-valley area NVA3-2 in the fourth direction DR4′ or the fifth direction DR5′. For example, the (3-1)^{th} non-valley area NVA3-1 and the (3-2)^{th} non-valley area NVA3-2 may be arranged to face each other in the fourth direction DR4′ or the fifth direction DR5′. The (3-1)^{th} non-valley area NVA3-1 and the (3-2)^{th} non-valley area NVA3-2 may overlap each other when viewed in the fourth direction DR4′ or the fifth direction DR5′.

In the display panel DP according to an embodiment, the valley areas VA1, VA2, and VA3 surrounding portions of the pixel areas PXA-B, PXA-R, and PXA-G may be defined to prevent a lateral leakage current from occurring between adjacent pixels. For example, in the description, the “lateral leakage current” means a current that flows in another direction crossing the third direction DR3 (see FIGS. 3C and 3D) other than a current that flows in the third direction DR3 (see FIGS. 3C and 3D) that is a laminated direction of the light emitting element OLED (see FIGS. 3C and 3D), for example, in a direction in which the image is displayed. The lateral leakage current may mean a current flowing in a direction parallel to a plane defined by the first direction DR1 (see FIGS. 3A and 3B) and the second direction DR2 (see FIGS. 3A and 3B).

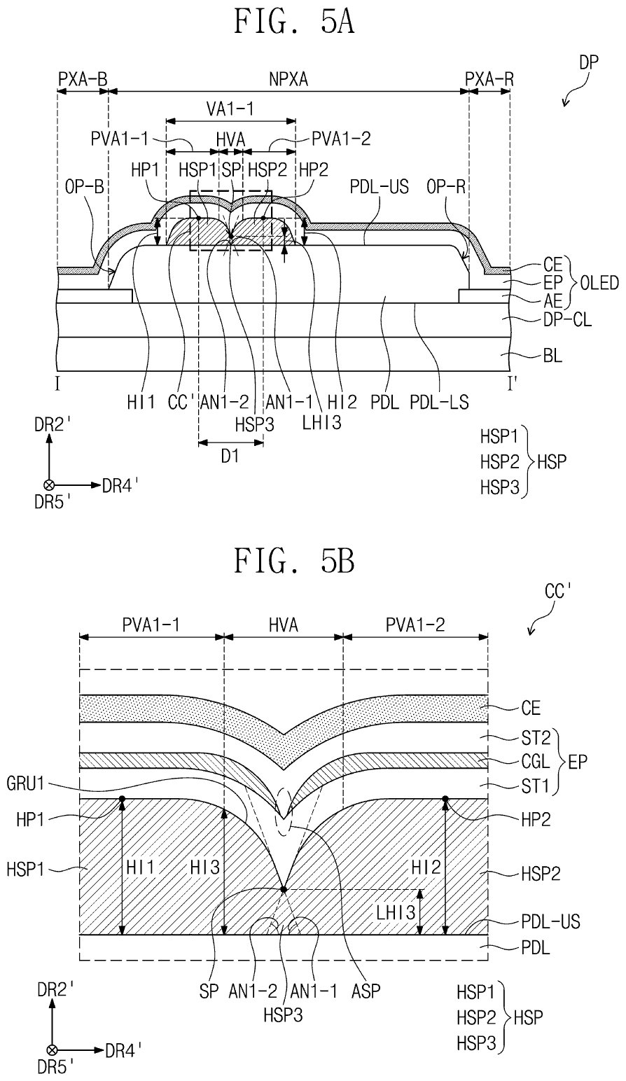

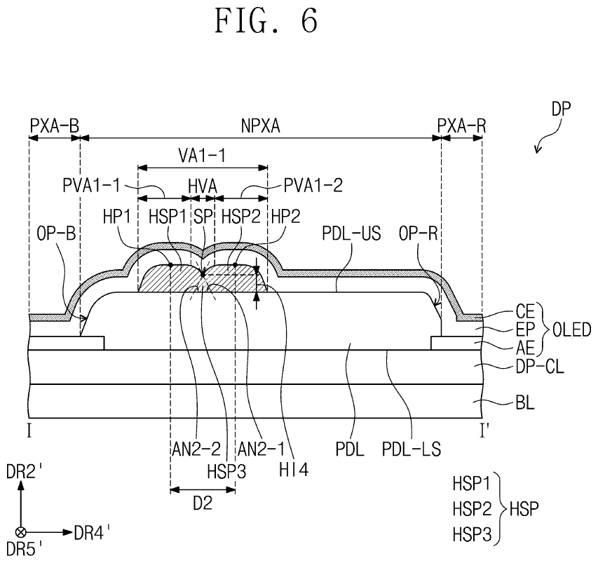

According to an embodiment, a separation pattern HSP (see FIG. 5A) may be disposed in the valley areas VA1, VA2, and VA3. The separation pattern HSP (see FIG. 5A) corresponding to the valley areas VA1, VA2, and VA3 may be defined. Accordingly, the lateral leakage current may be prevented, the color mixing between the adjacent pixels may be prevented, and a decrease in brightness may be prevented. A detailed description of the separation pattern HSP (see FIG. 5A) will be made below with reference to FIGS. 5A, 5B, and 6.

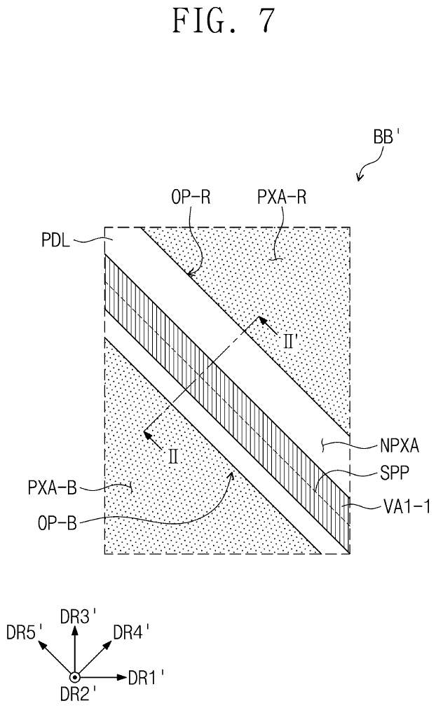

According to an embodiment, as described above, the separation pattern HSP (see FIG. 5A) may not be disposed in the valley areas VA1, VA2, and VA3. For example, a recessed part GRU2 (see FIG. 9) corresponding to the valley areas VA1, VA2, and VA3 may be defined in the pixel defining layer PDL. Accordingly, the lateral leakage current may be prevented, the color mixing between the adjacent pixels may be prevented, and a decrease in brightness may be prevented. A detailed description of the recessed part GRU2 (see FIG. 9) will be made below with reference to FIGS. 7 to 9.

According to an embodiment, the pixel defining layer PDL may include the non-valley areas NVA1, NVA2, and NVA3 defined as areas in which the valley patterns are not formed such that a driving voltage may be transmitted to the second electrode CE (see FIG. 3B). In an embodiment, at least one first non-valley area NVA1, at least one second non-valley area NVA2, and at least one third non-valley area NVA3 may be arranged so as not to face each other. In the description, the wording “arranged so as not to face each other” means that different non-valley patterns do not overlap each other in a portion in which the shortest distance between adjacent pixel areas is defined. In the description, the wording “different non-valley areas” means non-valley areas arranged on different virtual lines, respectively.

The first to third non-valley areas NVA1, NVA2, and NVA3 may be arranged so as not to face each other. In case that the first to third non-valley areas NVA1, NVA2, and NVA3 are defined to face each other, the lateral leakage current may occur between the adjacent pixels through the first to third non-valley areas NVA1, NVA2, and NVA3 facing each other. According to an embodiment, the first to third non-valley areas NVA1, NVA2, and NVA3 are arranged so as not to face each other, and thus the lateral leakage current may be prevented from occurring between the adjacent pixels through the first to third non-valley areas NVA1, NVA2, and NVA3 that face each other.

FIG. 4B is an enlarged schematic plan view of part BB′ of FIG. 4A according to an embodiment. In FIG. 4B, the (1-1)^{th} valley area VA1-1 may have been illustratively described, but the following description of the (1-1)^{th} valley area VA1-1 may be equally applied to the first valley area VA1 (see FIG. 4A), the second valley area VA2 (see FIG. 4A), and the third valley area VA3 (see FIG. 4A) of FIG. 4A.

Referring to FIG. 4B, the (1-1)^{th} valley area VA1-1 may extend in the fifth direction DR5′ and may be spaced a selected distance from the first pixel area PXA-B in the fourth direction DR4′. The (1-1)^{th} valley area VA1-1 may surround a portion of the first pixel opening OP-B. The first valley area VA1 may include a (1-1)^{th} valley part PVA1-1, an overlapping part HVA, and a (1-2)^{th} valley part PVA1-2.

The (1-1)^{th} valley part PVA1-1 may be adjacent to the first pixel area PXA-B and may extend along an exterior of the first pixel area PXA-B. The (1-1)^{th} valley part PVA1-1 may have a constant thickness in plan view or on a plane and extend in the fifth direction DR5′. The (1-1)^{th} valley part PVA1-1 may be closer to the first pixel area PXA-B than to the second pixel area PXA-R.

The (1-2)^{th} valley part PVA1-2 may be spaced farther from the first pixel opening OP-B than the (1-1)^{th} valley part PVA1-1. The (1-2)^{th} valley part PVA1-2 may have a shape corresponding to the (1-1)^{th} valley part PVA1-1. The (1-2)^{th} valley part PVA1-2 may have a constant thickness in plan view or on a plane and extend in the fifth direction DR5′. The (1-2)^{th} valley part PVA1-2 may be closer to the first pixel area PXA-B than to the second pixel area PXA-R. The (1-2)^{th} valley part PVA1-2 may be spaced a selected distance from the (1-1)^{th} valley part PVA1-1 in the fourth direction DR4′. A thickness of the (1-2)^{th} valley part PVA1-2 in the fourth direction DR4′ in plan view or on a plane may be substantially the same as a thickness of the (1-1)^{th} valley part PVA1-1 in the fourth direction DR4′ in plan view or on a plane.

The overlapping part HVA may be disposed between the (1-1)^{th} valley part PVA1-1 and the (1-2)^{th} valley part PVA1-2. Like the (1-1)^{th} valley part PVA1-1 and the (1-2)^{th} valley part PVA1-2, the overlapping part HVA may also extend in the fifth direction DR5′. Among long sides of the overlapping part HVA, a first long side adjacent to the first pixel area PXA-B may contact the (1-1)^{th} valley part PVA1-1. Among the long sides of the overlapping part HVA, a second long side adjacent to the second pixel area PXA-R may contact the (1-2)^{th} valley part PVA1-2. The (1-1)^{th} valley part PVA1-1, the (1-2)^{th} valley part PVA1-2, and the overlapping part HVA may constitute the (1-1)^{th} valley area (e.g., single (1-1)^{th} valley area) VA1-1 extending in the fifth direction DR5′ together.

The overlapping part HVA may be line-symmetric to a line defined by a lowest point SP, which will be described below. The lowest point SP may extend in the fifth direction DR5′. The line defined by the lowest point SP may overlap the overlapping part HVA in plan view or on a plane.

FIG. 5A is a schematic cross-sectional view along line I-I′ of FIG. 4B according to an embodiment. Hereinafter, a description of the (1-1)^{th} valley area VA1-1 may be equally applied to the first valley area VA1 (see FIG. 4A), the second valley area VA2 (see FIG. 4A), and the third valley area VA3 (see FIG. 4A) illustrated in FIG. 4A.

Referring to FIG. 5A, the display panel DP according to an embodiment may include the base layer BL, the circuit element layer DP-CL disposed on the base layer BL, and the light emitting element OLED disposed on the circuit element layer DP-CL. For example, the upper insulating layer TFL (see FIG. 3B) may be further disposed on the light emitting element OLED.

The light emitting element OLED disposed on the circuit element layer DP-CL may include the first electrode AE, a light emitting unit EP, and the second electrode CE that are sequentially laminated. The light emitting unit EP may be disposed on the pixel defining layer PDL and may overlap the first and second pixel areas PXA-B and PXA-R. The light emitting unit EP in FIG. 5A may include the first light emitting stack ST1 (see FIG. 3C), the charge generating layer CGL (see FIG. 3C), and the second light emitting stack ST2 (see FIG. 3C) described above in FIG. 3C. The first light emitting stack ST1 (see FIG. 3C) may include at least the first light emitting layer EML1 (see FIG. 3C), and the second light emitting stack ST2 (see FIG. 3C) may include at least the second light emitting layer EML2 (see FIG. 3C).

The pixel defining layer PDL may be disposed on the circuit element layer DP-CL. The first pixel opening OP-B and the second pixel opening OP-R, through which a portion of the first electrode AE is exposed, may be defined in the pixel defining layer PDL.

The separation pattern HSP may be disposed on the pixel defining layer PDL. The separation pattern HSP may overlap the (1-1)^{th} valley area VA1-1. The separation pattern HSP may include a first pattern part HSP1, a second pattern part HSP2, and a third pattern part HSP3. The separation pattern HSP may prevent the lateral leakage current from flowing along the charge generating layer CGL (see FIG. 3C) between the adjacent pixels to cause the color mixing between the adjacent pixels or the decrease in the brightness, and therefore may improve display quality of the display panel DP. This will be described below with reference to FIG. 5B.

The separation pattern HSP may include an organic photosensitive material. Accordingly, in case that the separation pattern HSP is formed, the organic photosensitive material may be cured or decomposed by irradiating a light. The separation pattern HSP may include a material that is cured in case that a light is irradiated. For example, the separation pattern HSP may include a negative photosensitive material. In case that the negative photosensitive material is used, and in case that development is performed by irradiating a light, an angle formed between an outer surface of the separation pattern HSP and an upper surface PDL-US of the pixel defining layer PDL may increase. The separation pattern HSP may include the first pattern part HSP1, the second pattern part HSP2, and the third pattern part HSP3.

The separation pattern HSP may have a shape in which two protrusions protruding convexly from an upper surface of the pixel defining layer PDL on a cross section partially overlap the overlapping part HVA. This is because an angle of the separation pattern HSP in the overlapping part HVA sharply changes, the charge generating layer CGL (see FIG. 5B) on the separation pattern HSP may be disconnected, and accordingly the lateral leakage current between the adjacent pixels may be prevented.

The first pattern part HSP1 may overlap the (1-1)^{th} valley part PVA1-1. The second pattern part HSP2 may overlap the (1-2)^{th} valley part PVA1-2. The third pattern part HSP3 may overlap the overlapping part HVA. The first pattern part HSP1 and the second pattern part HSP2 may have a symmetrical shape with respect to the third pattern part HSP3.

The first pattern part HSP1 may be a part that protrudes from the upper surface PDL-US of the pixel defining layer PDL to a maximum first height HI1. A distance from a first highest point HP1 of the first pattern part HSP1 to the upper surface PDL-US of the pixel defining layer PDL in the second direction DR2′ may be the first height HI1. The first pattern part HSP1 may be a part that convexly protrudes from the upper surface PDL-US of the pixel defining layer PDL. The second pattern part HSP2 may protrude from the upper surface PDL-US of the pixel defining layer PDL to a maximum second height HI2. A distance from a second highest point HP2 of the second pattern part HSP2 to the upper surface PDL-US of the pixel defining layer PDL in the second direction DR2′ may be the second height HI2. For example, the first height HI1 and the second height HI2 may be substantially the same as each other. For example, the first pattern part HSP1 and the second pattern part HSP2 may be parts that protrude convexly from the upper surface PDL-US of the pixel defining layer PDL.

The third pattern part HSP3 may protrude from the upper surface PDL-US of the pixel defining layer PDL to a maximum third height HI3 (see FIG. 5B) that is smaller than the first height HI1 and the second height HI2. The third pattern part HSP3 may be a part curved from an upper surface of the first pattern part HSP1 and an upper surface of the second pattern part HSP2 toward a lower surface PDL-LS of the pixel defining layer PDL. Accordingly, the third height HI3 (see FIG. 5B) that is a maximum height of the third pattern part HSP3 may be smaller than the first height HI1 and the second height HI2.

The third pattern part HSP3 may be disposed between the first pattern part HSP1 and the second pattern part HSP2. The third pattern part HSP3 may be a part recessed from the first pattern part HSP1 and the second pattern part HSP2 toward the upper surface PDL-US of the pixel defining layer PDL.

Angles AN1-1 and AN1-2 formed between a normal line of an outer surface of the third pattern part HSP3 and the upper surface PDL-US of the pixel defining layer PDL may increase as the angles AN1-1 and AN1-2 are closer to the lowest point SP of the third pattern part HSP3. The lowest point SP of the third pattern part HSP3 may be positioned at a center portion of the overlapping part HVA. Accordingly, a sum of the angles AN1-1 and AN1-2 formed between the normal line of the outer surface of the third pattern part HSP3 and the upper surface PDL-US of the pixel defining layer PDL at the lowest point SP may increase. This will be described below with reference to FIG. 5B.

The light emitting unit EP may be disposed on the separation pattern HSP and the pixel defining layer PDL. The light emitting unit EP may cover the separation pattern HSP. The light emitting unit EP may overlap the pixel areas PXA-R and PXA-B and the non-pixel area NPXA. As described above in FIG. 3C, the light emitting unit EP may include the first light emitting stack ST1 (see FIG. 3C), the charge generating layer CGL1 (see FIG. 3C), and the second light emitting stack ST2 (see FIG. 3C), and as described above in FIG. 3D, the light emitting unit EP may include the three light emitting stacks ST1, ST2, and ST3 (see FIG. 3D) and the two charge generating layers CGL1 and CGL2 (see FIG. 3D).

The second electrode CE may be disposed on the light emitting unit EP and cover the light emitting unit EP. The second electrode CE may overlap the pixel areas PXA-R and PXA-B and the non-pixel area NPXA.

The highest point of the first pattern part HSP1 and the highest point of the second pattern part HSP2 may be spaced a first distance D1 from each other in the fourth direction DR4′. As the first distance D1 increases, a minimum height LHI3 of the lowest point SP may decrease. Accordingly, portions having a large slope may meet each other at the lowest point SP, and the (1-1)^{th} angle AN1-1 and the (1-2)^{th} angle AN1-2 may increase. This means that a change in the slope at the lowest point SP increases, and accordingly, the charge generating layer CGL (see FIG. 5B) may be disconnected. However, in case that the first distance D1 is too large, the protrusions may not overlap each other, and thus the overlapping part HVA and the third pattern part HSP3 corresponding thereto may be removed. As the third pattern part HSP3, of which a slope sharply changes, is removed, the charge generating layer CGL may not be disconnected, and accordingly, the lateral leakage current may flow between the adjacent pixels. The first distance D1 may be in a range of about 3 m to about 5 m.

FIG. 5B is an enlarged schematic cross-sectional view of part CC′ of FIG. 5A according to an embodiment.

Referring to FIG. 5B, the light emitting unit EP may include the first light emitting stack ST1, the charge generating layer CGL, and the second light emitting stack ST2. The first light emitting stack ST1 may be disposed on a lower surface of the charge generating layer CGL. The second light emitting stack ST2 may be disposed on an upper surface of the charge generating layer CGL. Each of the first light emitting stack ST1 and the second light emitting stack ST2 may include the light emitting layers EML1 and EML2 (see FIG. 3C) that emit lights. The light emitting unit EP may have a shape corresponding to an upper surface of the third pattern part HSP3. The second electrode CE may have a shape corresponding to the upper surface of the third pattern part HSP3.

A recessed part GRU1 recessed toward the upper surface PDL-US of the pixel defining layer PDL may be defined on the upper surface of the third pattern part HSP3. As the recessed part GRU1 approaches the first pattern part HSP1 or the second pattern part HSP2, the recessed part GRU1 may be distant from the upper surface PDL-US of the pixel defining layer PDL. The light emitting unit EP may be disposed along the upper surface of the first pattern part HSP1, the upper surface of the second pattern part HSP2, and the recessed part GRU1.

The charge generating layer CGL may be disconnected at the lowest point SP of the third pattern part HSP3 closest to the upper surface PDL-US of the pixel defining layer PDL. The charge generating layer CGL may be disconnected at a position ASP corresponding to the lowest point SP of the third pattern part HSP3. The lowest point SP of the third pattern part HSP3 may be a section in which a slope of the outer surface of the third pattern part HSP3 sharply changes. For example, the charge generating layer CGL may be disconnected due to the sharply changing slope of the outer surface of the third pattern part HSP3. For example, the charge generating layer CGL disposed at the lowest point SP of the third pattern part HSP3 may be sharply bent and broken. Accordingly, the lateral leakage current may be prevented from flowing through the charge generating layer CGL in the fourth direction DR4′.

A common electrode CE disposed on the light emitting unit EP may not be disconnected on the third pattern part HSP3. Accordingly, the common electrode CE may supply a common voltage to the adjacent pixels.

The (1-1)^{th} angle AN1-1 and the (1-2)^{th} angle AN1-2 formed between the normal line of the outer surface of the third pattern part HSP3 and the upper surface PDL-US of the pixel defining layer PDL may increase as the (1-1)^{th} angle AN1-1 and the (1-2)^{th} angle AN1-2 are closer to the lowest point SP of the third pattern part HSP3. For example, the (1-1)^{th} angle AN1-1 may be an angle formed between the normal line of the outer surface of the third pattern part HSP3, which is close to the first pattern part HSP1, and the upper surface PDL-US of the pixel defining layer PDL. The (1-2)^{th} angle AN1-2 may be an angle formed between the normal line of the outer surface of the third pattern part HSP3, which is close to the second pattern part HSP2, and the upper surface PDL-US of the pixel defining layer PDL.

As the sum of the (1-1)^{th} angle AN1-1 and the (1-2)^{th} angle AN1-2 increases, a change in the slope of the outer surface of the third pattern part HSP3 may increase. Since the sum of the (1-1)^{th} angle AN1-1 and the (1-2)^{th} angle AN1-2 is greatest at the lowest point SP, the charge generating layer CGL may be disconnected on a position corresponding to the lowest point SP.

The (1-1)^{th} angle AN1-1 may be about 30 degrees or more, and the (1-2)^{th} angle AN1-2 may be about 30 degrees or more. The sum of the (1-1)^{th} angle AN1-1 and the (1-2)^{th} angle AN1-2 may be about 60 degrees or more. In case that the sum of the (1-1)^{th} angle AN1-1 and the (1-2)^{th} angle AN1-2 is less than about 60 degrees, a change in a slope of the third pattern part HSP3 is not too large, and thus the charge generating layer CGL may not be disconnected near the lowest point SP. However, in case that the sum of the (1-1)^{th} angle AN1-1 and the (1-2)^{th} angle AN1-2 is too large, there may be a risk of disconnection of the common electrode CE.

The sum of the (1-1)^{th} angle AN1-1 and the (1-2)^{th} angle AN1-2 may change according to the height LHI3 (hereinafter, referred to as a minimum height) of the lowest point SP from the upper surface PDL-US of the pixel defining layer PDL. As the minimum height LHI3 decreases, the sum of the (1-1)^{th} angle AN1-1 and the (1-2)^{th} angle AN1-2 may increase. As the minimum height LHI3 increases, the sum of the (1-1)^{th} angle AN1-1 and the (1-2)^{th} angle AN1-2 may decreases.

FIG. 6 is a schematic cross-sectional view along line I-I′ of FIG. 4B according to an embodiment. Hereinafter, the same reference numerals are used for the same components as those described in FIGS. 5A and 5B, and descriptions thereof will be omitted.

Referring to FIG. 6, a second distance D2 of the display panel DP of FIG. 6 may be smaller than the first distance D1 (see FIG. 5A) of the display panel DP (see FIG. 5A) of FIG. 5A. Accordingly, the first pattern part HSP1 and the second pattern part HSP2 are positioned closer to each other, and a minimum height HI4 of the lowest point SP may be greater than the minimum height LHI3 (see FIG. 5A) of the FIG. 5A.

The minimum height HI4 may be greater than the minimum height LHI3 (see FIG. 5A) of the display panel DP (see FIG. 5A) of FIG. 5A. Accordingly, a (2-1)^{th} angle AN2-1 may be smaller than the (1-1)^{th} angle AN1-1 (see FIG. 5A) of FIG. 5A, and a (2-2)^{th} angle AN2-2 may be smaller than the (1-2)^{th} angle AN1-2 (see FIG. 5A) of FIG. 5A. For example, the change in the slope of the outer surface of the third pattern part HSP3 at the lowest point SP decreases, which may cause the possibility that the charge generating layer CGL is not disconnected. Thus, the display panel DP (see FIG. 5A) of FIG. 5A is more suitable than the display panel DP of FIG. 6.

FIG. 7 is an enlarged schematic plan view of part BB′ of FIG. 4A according to an embodiment. In FIG. 7, the (1-1)^{th} valley area VA1-1 has been illustratively described, but the following description of the (1-1)^{th} valley area VA1-1 may be equally applied to the first valley area VA1 (see FIG. 4A), the second valley area VA2 (see FIG. 4A), and the third valley area VA3 (see FIG. 4A) of FIG. 4A.

Referring to FIG. 7, the (1-1)^{th} valley area VA1-1 may extend in the fifth direction DR5′ and may be spaced a selected distance from the first pixel area PXA-B in the fourth direction DR4′. The (1-1)^{th} valley area VA1-1 may surround a portion of the first pixel opening OP-B. The (1-1)^{th} valley area VA1-1 may be line symmetrical with respect to a line defined by the lowest point SP. The line defined by the lowest point SP may extend in the fifth direction DR5′. The line defined by the lowest point SP may overlap the (1-1)^{th} valley area VA1-1 in plan view or on a plane.

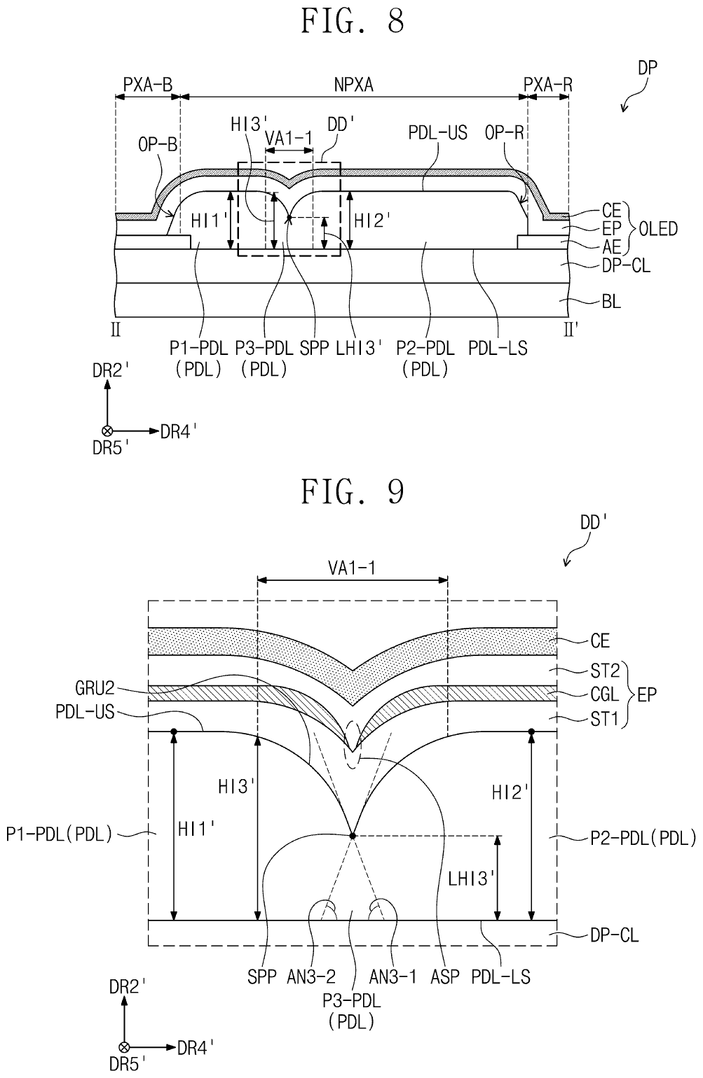

FIG. 8 is a schematic cross-sectional view along line II-II of FIG. 7 according to an embodiment. Hereinafter, the same reference numerals are used for the same components as those described above, and a description thereof will be omitted.

Referring to FIG. 8, the recessed part GRU2 (see FIG. 9) that overlaps the (1-1)^{th} valley area VA1-1 may be defined in the pixel defining layer PDL. The pixel defining layer PDL may include a first part P1-PDL, a second part P2-PDL, and a third part P3-PDL. A maximum height of the first part P1-PDL from the lower surface PDL-LS to the upper surface PDL-US of the pixel defining layer PDL may be a first height HI1′. A maximum height of the second part P2-PDL from the lower surface PDL-LS to the upper surface PDL-US of the pixel defining layer PDL may be a second height HI2′. The first height HI1′ and the second height HI2′ may be substantially the same as each other.

The third part P3-PDL may be disposed between the first part P1-PDL and the second part P2-PDL, and a maximum height of the third part P3-PDL from the lower surface PDL-LS to the upper surface PDL-US of the pixel defining layer PDL may be a third height HI3′. The third height HI3 may be smaller than the first and second heights HIP and HI2′. The third part P3-PDL may be a part recessed from the first part P1-PDL and the second part P2-PDL toward the lower surface PDL-LS of the pixel defining layer PDL.

A change in the slope of the outer surface of the third part P3-PDL may be large at a lowest point SPP of the third part P3-PDL. Accordingly, the charge generating layer CGL (see FIG. 9) disposed near the lowest point SPP may be disconnected.

The pixel defining layer PDL may include an organic photosensitive material. The pixel defining layer PDL may include a light-curable material. For example, the pixel defining layer PDL may include a negative photosensitive material. In case that the negative photosensitive material is used, and in case that development is performed by irradiating a light, an angle formed between an outer surface of the pixel defining layer PDL and the lower surface PDL-LS of the pixel defining layer PDL may increase.

FIG. 9 is an enlarged schematic cross-sectional view of part DD′ of FIG. 8 according to an embodiment.

Referring to FIG. 9, the recessed part GRU2 recessed toward the lower surface PDL-LS of the pixel defining layer PDL may be defined on an upper surface of the third part P3-PDL. The light emitting unit EP may be disposed along an upper surface of the first part P1-PDL, an upper surface of the second part P2-PDL, and the recessed part GRU2.

The charge generating layer CGL may be disconnected at the lowest point SPP of the third part P3-PDL closest to the lower surface PDL-LS of the pixel defining layer PDL among the recessed part GRU2. The charge generating layer CGL may be disconnected at the position ASP corresponding to the lowest point SPP of the third part P3-PDL. The lowest point SPP of the third part P3-PDL may be a section in which the slope of the outer surface of the third part P3-PDL sharply changes. For example, the charge generating layer CGL may be disconnected due to the sharply changing slope of the outer surface of the third part P3-PDL. For example, the charge generating layer CGL disposed at the lowest point SPP of the third part P3-PDL may be sharply bent and broken. Accordingly, the lateral leakage current may be prevented from flowing through the charge generating layer CGL in the fourth direction DR4′.

The common electrode CE disposed on the light emitting unit EP may not be disconnected on the third part P3-PDL. Accordingly, the common electrode CE may supply a common voltage to the adjacent pixels.

A (3-1)^{th} angle AN3-1 and a (3-2)^{th} angle AN3-2 formed between a normal line of an outer surface of the third part P3-PDL and the lower surface PDL-LS of the pixel defining layer PDL may increase as the (3-1)^{th} angle AN3-1 and a (3-2)^{th} angle AN3-2 are closer to the lowest point SPP of the third part P3-PDL. For example, the (3-1)^{th} angle AN3-1 may be an angle formed between the normal line of the outer surface of the third part P3-PDL, which is close to the first part P1-PDL, and the lower surface PDL-LS of the pixel defining layer PDL. The (3-2)^{th} angle AN3-2 may be an angle formed between the normal line of the outer surface of the third part P3-PDL, which is close to the second part P2-PDL, and the lower surface PDL-LS of the pixel defining layer PDL.

As a sum of the (3-1)^{th} angle AN3-1 and the (3-2)^{th} angle AN3-2 increases, the change in the slope of the outer surface of the third part P3-PDL may increase. Since the sum of the (3-1)^{th} angle AN3-1 and the (3-2)^{th} angle AN3-2 is greatest at the lowest point SPP, the charge generating layer CGL may be disconnected at a position corresponding to the lowest point SPP.

The (3-1)^{th} angle AN3-1 may be about 30 degrees or more, and the (3-2)^{th} angle AN3-2 may be about 30 degrees or more. The sum of the (3-1)^{th} angle AN3-1 and the (3-2)^{th} angle AN3-2 may be about 60 degrees or more. In case that the sum of the (3-1)^{th} angle AN3-1 and the (3-2)^{th} angle AN3-2 is less than about 60 degrees, a change in a slope of the third part P3-PDL may not be too large, and thus the charge generating layer CGL may not be disconnected near the lowest point SPP. However, in case that the sum of the (3-1)^{th} angle AN3-1 and the (3-2)^{th} angle AN3-2 is too large, there may be a risk of disconnection of the common electrode CE.

The sum of the (3-1)^{th} angle AN3-1 and the (3-2)^{th} angle AN3-2 may change according to a height LHI3′ (hereinafter, referred to as a minimum height) of the lowest point SPP from the upper surface PDL-US of the pixel defining layer PDL. As the minimum height LHI3′ decreases, the sum of the (3-1)^{th} angle AN3-1 and the (3-2)^{th} angle AN3-2 may increase. As the minimum height LHI3′ increases, the sum of the (3-1)^{th} angle AN3-1 and the (3-2)^{th} angle AN3-2 may decreases.

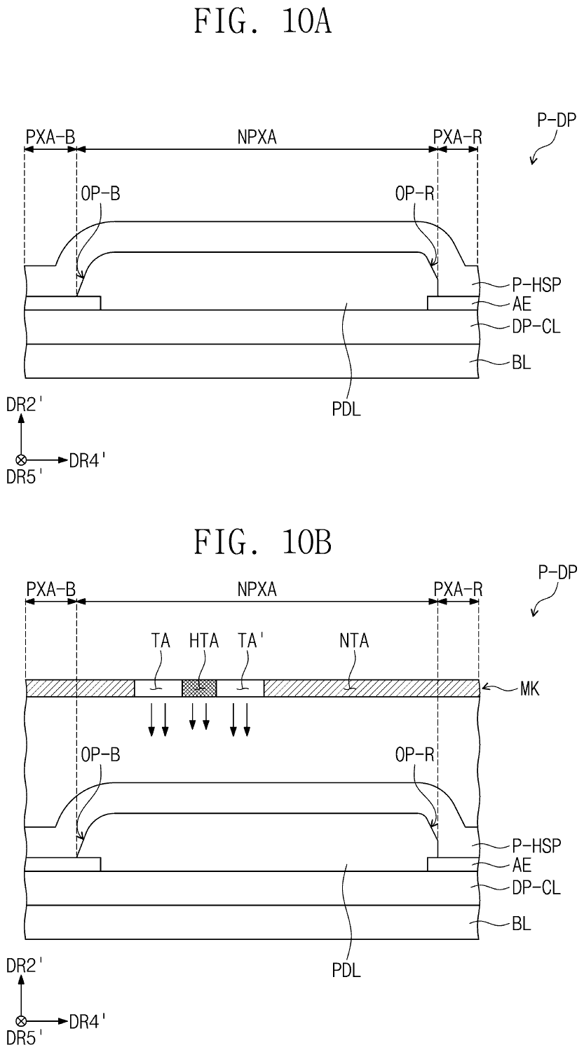

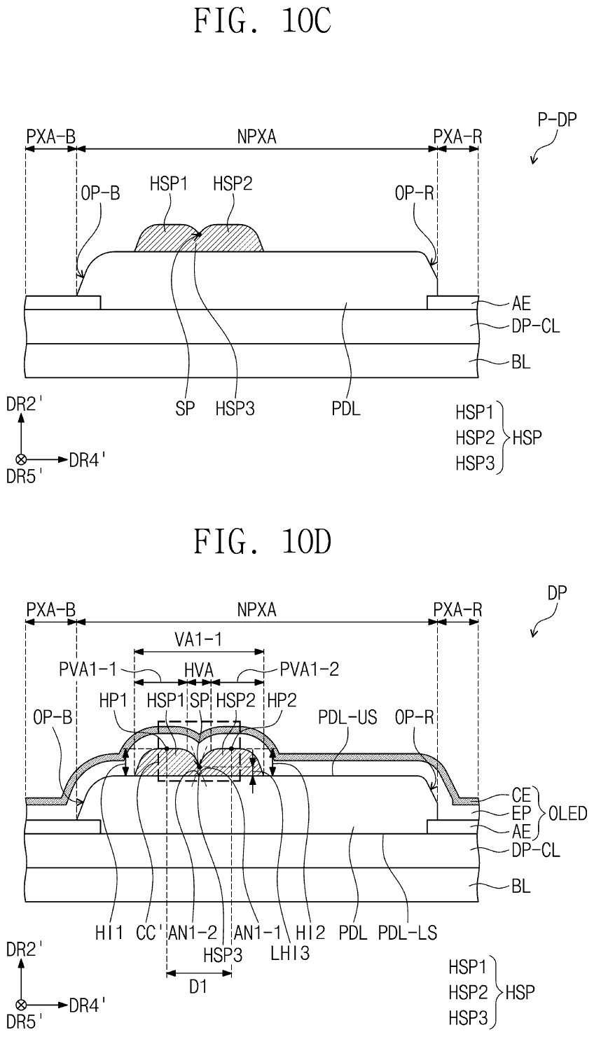

FIGS. 10A to 10D are schematic cross-sectional views illustrating a portion of a method of manufacturing a display device according to an embodiment. Hereinafter, the same reference numerals are used for the same components as those described above, and a description thereof will be omitted.

Referring to FIG. 10A, a preliminary separation pattern layer P-HSP may be formed on a preliminary display device P-DP including the base layer BL including the pixel areas PXA-B and PXA-R and the non-pixel area NPXA and the pixel defining layer PDL which is disposed on the base layer BL and in which the pixel openings OP-B and OP-R corresponding to the pixel areas PXA-B and PXA-R are defined. The preliminary separation pattern layer P-HSP may be disposed (e.g., directly disposed) on the upper surface of the pixel defining layer PDL. The preliminary separation pattern layer P-HSP may overlap the non-pixel area NPXA. The preliminary separation pattern layer P-HSP may overlap the pixel defining layer PDL.

Referring to FIG. 10B, the separation pattern HSP (see FIG. 10C) may be formed by exposing a light onto the preliminary separation pattern layer P-HSP using a mask MK including transmissive areas TA and TA′, a non-transmissive area NTA, and a semi-transmissive area HTA disposed between the transmissive areas TA and TA′. For example, the mask MK may be a half-tone mask. The preliminary separation pattern layer P-HSP may include a material that is cured in case that a light is irradiated.

The non-transmissive area NTA of the mask MK may be an area through which a light may not pass. The transmissive area TA of the mask MK may be an area through which a light may pass. The semi-transmissive area HTA may be an area through which a smaller amount of light than that of the transmissive area TA passes.

Since the preliminary separation pattern layer P-HSP contains a negative photosensitive material, which is a material that is cured in case that a light is irradiated, the preliminary separation pattern layer P-HSP at a portion corresponding to the non-transmissive area NTA may be removed. The preliminary separation pattern layer P-HSP at a portion corresponding to the transmissive area TA may be cured and remain. The preliminary separation pattern layer P-HSP at a portion corresponding to the semi-transmissive area HTA may be partially cured and remain. The preliminary separation pattern layer P-HSP at a portion corresponding to the transmissive area TA may include the first pattern part HSP1 (see FIG. 10C) and the second pattern part HSP2 (see FIG. 10C). The preliminary separation pattern layer P-HSP at the portion corresponding to the semi-transmissive area HTA may include the third pattern part HSP3 (see FIG. 10C).

Referring to FIG. 10C, the separation pattern HSP may be formed through exposure and then development using the mask MK (see FIG. 10B). The separation pattern HSP may include the first pattern part HSP1, the second pattern part HSP2, and the third pattern part HSP3 disposed between the first pattern part HSP1 and the second pattern part HSP2. A flow occurs in the preliminary separation pattern layer P-HSP (see FIG. 10B) during the development, and thus the separation pattern HSP may be formed in a continuous curved shape with no step on a cross section.

Referring to FIG. 10D, the light emitting unit EP including the charge generating layer CGL (see FIG. 5B) may be formed on the separation pattern HSP. The charge generating layer CGL (see FIG. 5B) may be disconnected at the lowest point SP of the third pattern part HSP3 corresponding to the semi-transmissive area HTA (see FIG. 10B) of the separation pattern HSP. For example, the charge generating layer CGL (see FIG. 5B) may be disconnected due to a sudden change in slope at the lowest point SP. This has been described above in detail, a description thereof will be omitted.

The display panel DP may be formed by forming the common electrode CE, which covers the light emitting unit EP and the pixel defining layer PDL, on the light emitting unit EP. The common electrode CE may overlap the non-pixel area NPXA and the pixel areas PXA-B and PXA-R and may be continuously formed without disconnection.

As described above with reference to FIGS. 10A to 10D, the separation pattern HSP may be formed using the half-tone mask MK. This may simplify a manufacturing process and reduce manufacturing costs as compared to the related art in which, to form a separator on the pixel defining layer PDL, a separate metal layer is formed on the pixel defining layer PDL, a photoresist is exposed and developed on the pixel defining layer PDL, the metal layer is wet-etched, the pixel defining layer PDL is dry-etched, the photoresist is removed, and then the remaining metal layer is wet-etched. Further, in the case of the method of manufacturing a display device according to an embodiment, a separate wet etching process is not required, and thus the pixels may be prevented from being damaged in the wet etching process.

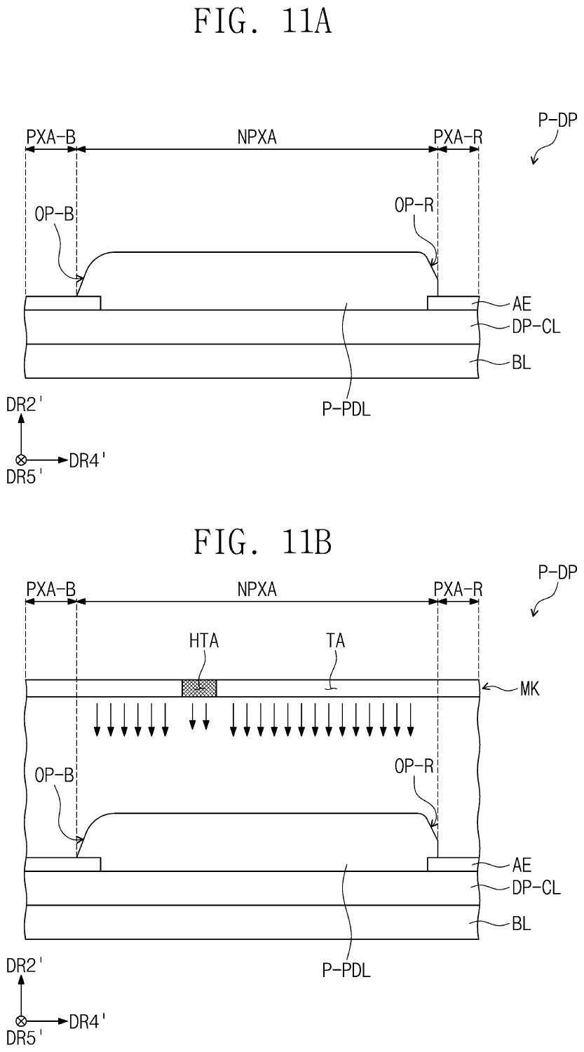

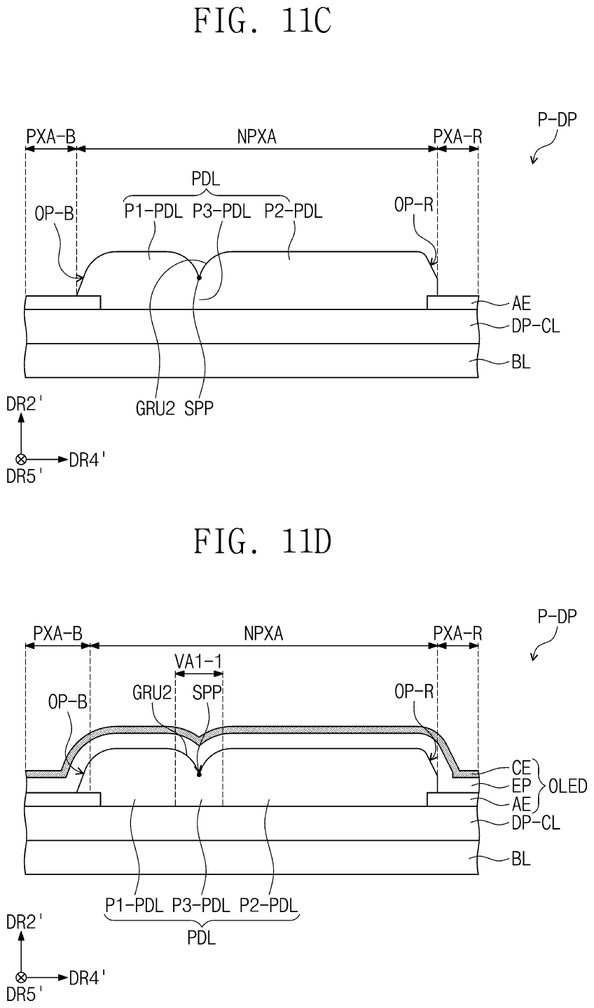

FIGS. 11A to 11D are schematic cross-sectional views illustrating a portion of the method of manufacturing the display device according to an embodiment. Hereinafter, the same reference numerals are used for the same components as those described above, and a description thereof will be omitted.

Referring to FIG. 11A, the preliminary display device P-DP including the base layer BL including the pixel areas PXA-B and PXA-R and the non-pixel area NPXA and the preliminary pixel defining layer P-PDL which is disposed on the base layer BL and in which the pixel openings OP-B and OP-R corresponding to the pixel areas PXA-B and PXA-R are defined may be prepared. For example, the preliminary pixel defining layer P-PDL may include an organic photosensitive material. The preliminary pixel defining layer P-PDL may include a material that is cured in case that a light is irradiated.

Referring to FIG. 11B, exposure may be performed on the preliminary pixel defining layer P-PDL using the mask MK. The mask MK may include the transmissive area TA through which a light passes and the semi-transmissive area HTA through which a light partially passes. The third part P3-PDL (see FIG. 11C) in which the recessed part GRU2 (see FIG. 11C) is defined may be formed by exposing and developing the preliminary pixel defining layer P-PDL using the mask MK.

Since the preliminary pixel defining layer P-PDL contains a negative photosensitive material which is a material that is cured in case that a light is irradiated, the preliminary pixel defining layer P-PDL at the portion corresponding to the transmissive area TA may be cured and remain. The preliminary pixel defining layer P-PDL at the portion corresponding to the semi-transmissive area HTA may be partially cured and remain. The pixel defining layer PDL at the portion corresponding to the transmissive area TA may include the first part P1-PDL (see FIG. 11C) and the second part P2-PDL (see FIG. 11C). The pixel defining layer PDL at the portion corresponding to the semi-transmissive area HTA may include the third part P3-PDL (see FIG. 11C).

Referring to FIG. 11D, the light emitting unit EP including the charge generating layer CGL (see FIG. 9) may be formed on the pixel defining layer PDL. The charge generating layer CGL (see FIG. 9) may be disconnected at the lowest point SPP of the third part P3-PDL corresponding to the semi-transmissive area HTA (see FIG. 11B) of the pixel defining layer PDL. For example, the charge generating layer CGL (see FIG. 9) may be disconnected due to a sudden change in slope at the lowest point SPP.

The display panel DP may be formed by forming the common electrode CE, which covers the light emitting unit EP and the pixel defining layer PDL, on the light emitting unit EP. The common electrode CE may overlap the non-pixel area NPXA and the pixel areas PXA-B and PXA-R and may be continuously formed without disconnection.

A display device according to an embodiment may include a separation pattern surrounding a portion of a pixel area, and a charge generating layer may be disconnected on the separation pattern. Therefore, a lateral leakage current may be prevented and color mixing between adjacent pixels may be prevented, and thus display quality may be improved, and a decrease in brightness may be prevented.

In a method of manufacturing a display device according to an embodiment, a separation pattern is formed using a half-tone mask including a semi-transmissive area, a separator may be formed without a separate additional process, and thus manufacturing processes may be simplified, and manufacturing costs may be reduced.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a base layer including a pixel area and a non-pixel area;
a pixel defining layer disposed on the base layer and including a pixel opening corresponding to the pixel area;
a light emitting unit disposed on the pixel defining layer, overlapping the pixel area, and including a charge generating layer; and
a separation pattern disposed on the pixel defining layer and overlapping a valley area among the valley area and a non-valley area arranged on a virtual line surrounding the pixel opening, wherein
the separation pattern includes:
a first pattern part protruding from an upper surface of the pixel defining layer to a first height;
a second pattern part protruding from the upper surface of the pixel defining layer to a second height that is substantially same as the first height; and
a third pattern part disposed between the first pattern part and the second pattern part and recessed from the first pattern part and the second pattern part toward the upper surface of the pixel defining layer, and
the charge generating layer is disconnected on the third pattern part.

2. The display device of claim 1, wherein the third pattern part protrudes from the upper surface of the pixel defining layer to a third height that is smaller than the first height and the second height.

3. The display device of claim 1, wherein the separation pattern is made of an organic photosensitive material.

4. The display device of claim 1, wherein
the valley area includes:
a (1-1)^{th} valley part surrounding a portion of the pixel opening;
a (1-2)^{th} valley part spaced farther from the pixel opening than the (1-1)^{th} valley part and having a shape corresponding to the (1-1)^{th} valley part; and
an overlapping part disposed between the (1-1)^{th} valley part and the (1-2)^{th} valley part, and
the first pattern part overlaps the (1-1)^{th} valley part, the second pattern part overlaps the (1-2)^{th} valley part, and the third pattern part overlaps the overlapping part.

5. The display device of claim 4, wherein the separation pattern has a shape in which two protrusions protruding convexly from the upper surface of the pixel defining layer partially overlap the overlapping part on a cross section.

6. The display device of claim 4, wherein a lowest point of the third pattern part is positioned at a center portion of the overlapping part.

7. The display device of claim 1, wherein the charge generating layer is disconnected at a lowest point of the third pattern part, which is closest to the upper surface of the pixel defining layer.

8. The display device of claim 1, wherein the separation pattern includes a material that is cured in case that a light is irradiated.

9. The display device of claim 1, wherein
the pixel area includes a first pixel area and a second pixel area spaced apart from the first pixel area,
the pixel opening includes a first pixel opening corresponding to the first pixel area and a second pixel opening corresponding to the second pixel area,
the non-valley area includes a first non-valley area disposed on a portion of a first virtual line surrounding the first pixel opening and a second non-valley area disposed on a portion of a second virtual line surrounding the second pixel opening, and
the first non-valley area and the second non-valley area do not face each other.

10. The display device of claim 1, wherein
the light emitting unit includes:
a first light emitting stack disposed on a lower surface of the charge generating layer; and
a second light emitting stack disposed on an upper surface of the charge generating layer, and
each of the first light emitting stack and the second light emitting stack includes a light emitting layer that emits a light.

11. The display device of claim 1, wherein an angle formed between a normal line of an outer surface of the third pattern part and the upper surface of the pixel defining layer increases as the angle is closer to a lowest point of the third pattern part.

12. The display device of claim 1, further comprising:
a common electrode disposed on the light emitting unit and overlapping the pixel area and the non-pixel area,
wherein the common electrode is not disconnected on the third pattern part.

13. A display device comprising:
a base layer including a pixel area and a non-pixel area;
a pixel defining layer disposed on the base layer and including a pixel opening corresponding to the pixel area; and
a light emitting unit disposed on the pixel defining layer, overlapping the pixel area, and including a charge generating layer, wherein
a recessed part overlapping a valley area among the valley area and a non-valley area arranged on a virtual line surrounding the pixel opening is defined in the pixel defining layer, and
the charge generating layer is disconnected at a lowest point of the recessed part closest to a lower surface of the pixel defining layer.

14. The display device of claim 13, wherein the pixel defining layer includes a material that is cured in case that a light is irradiated.

15. The display device of claim 13, wherein the pixel defining layer includes:
a first part of which a maximum height from the lower surface to an upper surface of the pixel defining layer is a first height;
a second part of which a maximum height from the lower surface to the upper surface of the pixel defining layer is a second height that is substantially same as the first height; and
a third part disposed between the first part and the second part, the third part of which a maximum height from the lower surface to the upper surface of the pixel defining layer is a third height that is smaller than the first height and the second height.

16. The display device of claim 13, wherein an angle formed between a normal line of an outer surface of the recessed part and the lower surface of the pixel defining layer increases as the angle is closer to the lowest point of the recessed part.

17. A method of manufacturing a display device, the method comprising:
forming a preliminary separation pattern layer on a preliminary display device including a base layer including a pixel area and a non-pixel area and a pixel defining layer disposed on the base layer and including a pixel opening corresponding to the pixel area;
forming a separation pattern by exposing a light onto the preliminary separation pattern layer using a mask including a transmissive area, a non-transmissive area, and a semi-transmissive area; and
forming a light emitting unit including a charge generating layer on the separation pattern,
wherein the charge generating layer is disconnected on a portion of the separation pattern, which corresponds to the semi-transmissive area.

18. The method of claim 17, wherein
the separation pattern includes:
a first pattern part protruding from an upper surface of the pixel defining layer to a first height;
a second pattern part protruding from the upper surface of the pixel defining layer to a second height that is substantially same as the first height; and
a third pattern part disposed between the first pattern part and the second pattern part and recessed from the first pattern part and the second pattern part toward the upper surface of the pixel defining layer,
the first pattern part and the second pattern part correspond to the transmissive area, and the third pattern part corresponds to the semi-transmissive area, and
the charge generating layer is disconnected on the third pattern part.

19. The method of claim 18, wherein the charge generating layer is disconnected at a lowest point of the third pattern part, which is closest to the upper surface of the pixel defining layer.

20. The method of claim 17, wherein the preliminary separation pattern layer includes a material that is cured in case that a light is irradiated.
